(19) United States
(12) Patent Application Publication
(10) Pub. No.: US 2022/0084838 A1
(43) Pub. Date: Mar. 17, 2022

(54) METAL ATOMIC LAYER ETCH AND DEPOSITION APPARATUSES AND PROCESSES WITH METAL-FREE LIGANDS

(71) Applicant: LAM RESEARCH CORPORATION, Fremont, CA (US)

(72) Inventors: He ZHANG, Fremont, CA (US); Yunsang KIM, Monte Sereno, CA (US); Dong Woo PAENG, Albany, CA (US)

(21) Appl. No.: 17/419,841

(22) PCT Filed: Jan. 7, 2020
(86) PCT No.: PCT/US2020/012518

§ 371 Date: Jun. 30, 2021

Related U.S. Application Data
(60) Provisional application No. 62/832,932, filed on Apr. 12, 2019.
(60) Provisional application No. 62/792,519, filed on Jan. 15, 2019.

(51) Int. Cl. H01L 21/3213; H01L 21/67

(52) U.S. Cl. CPC H01L 21/32136; C23C 16/45544; H01L 21/67069; H01L 21/32138

(57) ABSTRACT

An ALE system for performing a metal ALE process to etch a surface of a substrate includes a processing chamber, a substrate support, a heat source, a delivery system, and a controller. The substrate support is disposed in the processing chamber and supports the substrate. The delivery system supplies a ligand or organic species to the processing chamber. The controller controls the delivery system and the heat source to perform an isotropic metal ALE process that includes: during an iteration of the isotropic metal ALE process, performing atomistic adsorption and pulsed thermal annealing; during the atomistic adsorption, exposing the surface to the ligand or organic species, where the ligand or organic species is void of a metal precursor and is selectively adsorbed to form a metal complex in the surface; and during the pulsed thermal annealing, pulsing the heat source multiple times to remove the metal complex from the substrate.

### CROSS-REFERENCE TO RELATED APPLICATIONS

The present disclosure claims the benefit of U.S. Provisional Patent Application Nos. 62/832,932, filed on Apr. 12, 2019 and 62/792,519, filed on Jan. 15, 2019. The entire disclosures of the applications referenced above are incorporated herein by reference.

### FIELD

The present disclosure relates to substrate etching and deposition processes, and more particularly to atomic layer etching and deposition.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

During atomic layer etching (ALE) of a substrate, such as a semiconductor wafer, a monolayer of the substrate is removed during each cycle. A reactant gas is introduced into a processing chamber to modify a surface of the substrate. For example, a gas including a halide species is often used during ALE of silicon (Si), germanium (Ge) and metal oxides (MOₓ) to provide a halide-infused top layer. For example, gas including molecular chlorine species may be introduced to convert a surface layer of a Si substrate from Si to silicon chloride (SiClₓ), where x is 1, 2, 3, or 4. After surface layer modification, the processing chamber is purged. Plasma is used to remove the modified surface layer followed by purging of by-products.

During metal ALE of a substrate, a metal ligand is introduced using a metal precursor to modify a metal oxide surface of the substrate. Metal ALE is limited in speed and selectivity. Using plasma during ALE can cause structural damage. For example, substrates including magnetic random access memory (MRAM) devices may be damaged. Metal ALE is also limited to removal of certain types of metals.

### SUMMARY

An ALE system for performing a metal ALE process to etch a surface of a substrate is provided. The ALE system includes a processing chamber, a substrate support, a first heat source, a delivery system, and a controller. The substrate support is disposed in the processing chamber and is configured to support the substrate. The delivery system is configured to supply at least one of a ligand or an organic species to the processing chamber. The controller is configured to control the delivery system and the first heat source to perform an isotropic metal ALE process. The isotropic metal ALE process includes: during an iteration of the isotropic metal ALE process, performing atomistic adsorption and pulsed thermal annealing; during the atomistic adsorption, exposing the surface of the substrate to the at least one of the ligand or the organic species, where the at least one of the ligand or the organic species is void of a metal precursor and is selectively adsorbed to form a metal complex in the surface of the substrate; and during the pulsed thermal annealing, pulsing the first heat source on and off multiple times to remove the metal complex from the substrate.

In other features, the surface includes at least one of a metal, a metal oxide, or a metal nitride. In other features, during the isotropic metal ALE process, the surface of the substrate is not exposed to a metal precursor.

In other features, the isotropic metal ALE process includes preheating the substrate, via a second heat source, prior to performing the atomistic adsorption. In other features, the isotropic metal ALE process includes preheating the substrate to a temperature greater than or equal to an ambient temperature and less than a boiling point temperature of the metal complex.

In other features, the isotropic metal ALE process includes modifying the surface prior to performing the atomistic adsorption. In other features, the modifying of the surface includes supplying a gas to react with the surface of the substrate without striking plasma. In other features, the modifying of the surface includes supplying a gas to react with the surface of the substrate and striking plasma. In other features, the surface includes the metal and the modifying of the surface includes converting the metal to a metal oxide or a metal halide.

In other features, during the atomistic adsorption, the surface of the substrate is exposed to the ligand. The ligand is a reactive free ligand. In other features, the ligand is selected from a group consisting of hexafluroacetylacetone (Hhfac) and acetylacetone (Hacac). In other features, the ligand is selected from a group consisting of molecular chlorine (Cl₂), ethanol (EtOH), and an organic vapor.

In other features, the isotropic metal ALE process includes a first modification operation and a second modification operation. The atomistic adsorption corresponds to the second modification operation. The controller is configured to perform a predetermined number of iterations of the isotropic metal ALE process. Each of the predetermined number of iterations includes at least one of (i) supplying a different chemical species during the first modification operation than is supplied during a previous iteration of the isotropic metal ALE process, or (ii) supplying a different chemical species during the second modification operation than is supplied during a previous iteration of the isotropic metal ALE process.

In other features, a metal ALE method for etching a surface of a substrate is provided. The metal ALE method includes: disposing the substrate on a substrate support in a processing chamber; a delivery system configured to supply at least one of a ligand or an organic species to the processing chamber; and performing an isotropic metal ALE process. The isotropic metal ALE process includes: during an iteration of the isotropic metal ALE process, performing atomistic adsorption and pulsed thermal annealing; during the atomistic adsorption, exposing the surface of the substrate to the at least one of the ligand or the organic species, where the at least one of the ligand or the organic species is void of a metal precursor and is selectively adsorbed into the surface of the substrate to form a metal complex; and during the pulsed thermal annealing, pulsing a heat source on and off multiple times to remove the metal complex from the substrate.

In other features, the surface includes at least one of a metal, a metal oxide, or a metal nitride. In other features, during the isotropic metal ALE process, the surface of the substrate is not exposed to a metal precursor. In other features, the isotropic metal ALE process includes preheating the substrate prior to performing the atomistic adsorption to a temperature greater than or equal to an ambient temperature and less than a boiling point temperature of the metal complex.

In other features, the isotropic metal ALE process includes modifying the surface prior to performing the atomistic adsorption. In other features, the modifying of the surface includes supplying a gas to react with the surface of the substrate without striking plasma. In other features, the modifying of the surface includes supplying a gas to react with the surface of the substrate and striking plasma. In other features, the surface includes the metal and the modifying of the surface includes converting the metal to a metal oxide or a metal halide.

In other features, during the atomistic adsorption, the surface of the substrate is exposed to the ligand and the ligand is a reactive free ligand. In other features, the ligand is selected from a group consisting of hexafluroacetylacetone (Hhfac) and acetylacetone (Hacac). In other features, the ligand is a reactive free ligand selected from a group consisting of molecular chlorine (Cl₂), ethanol (EtOH), and an organic vapor.

In other features, the isotropic metal ALE process includes a first modification operation and a second modification operation. The atomistic adsorption corresponds to the second modification operation. A predetermined number of iterations of the isotropic metal ALE process are performed. Each of the predetermined number of iterations includes at least one of (i) supplying a different chemical species during the first modification operation than is supplied during a previous iteration of the isotropic metal ALE process, or (ii) supplying a different chemical species during the second modification operation than is supplied during a previous iteration of the isotropic metal ALE process.

In other features, an ALE system for performing a metal ALE process to etch a surface of a substrate is provided. The ALE system includes a processing chamber, a substrate support, a heat source, a delivery system and a controller. The substrate support is disposed in the processing chamber and configured to support the substrate. The heat source is configured to heat at least one of the substrate support or the processing chamber. The delivery system is configured to supply at least one of a ligand or an organic species to the processing chamber. The controller is configured to control the delivery system and the heat source to perform an isotropic metal ALE process including. During an iteration of the isotropic metal ALE process, the surface is modified and atomistic adsorption and thermal annealing are performed. During the modifying of the surface, a gas is supplied to react with the surface of the substrate. During the atomistic adsorption, the surface of the substrate is exposed to the at least one of the ligand or the organic species. The at least one of the ligand or the organic species is void of a metal precursor and is selectively adsorbed to form a metal complex in the surface of the substrate. During the thermal annealing, the heat source is activated to remove the metal complex from the substrate.

In other features, the gas includes oxygen (O₂). In other features, the ligand includes chlorine (Cl₂). In other features, the thermal annealing includes (i) not pulsing the heat source, or (ii) pulsing the heat source with extended pulses having lengths greater than or equal to a predetermined length.

In other features, an ALE system for performing a metal ALE process to etch a surface of a substrate is provided. The ALE system includes a processing chamber, a substrate support, a heat source, a delivery system, and a controller. The substrate support is disposed in the processing chamber and configured to support the substrate. The heat source is configured to heat at least one of the substrate support or the processing chamber. The delivery system is configured to supply at least one of a ligand or an organic species to the processing chamber. The controller is configured to control the delivery system and the heat source to perform a selective metal ALE process including: during an iteration of the selective metal ALE process, modifying the surface, performing atomistic adsorption and pulsed thermal annealing; and during the modifying of the surface, supplying a gas to react with selective portions of the surface of the substrate. The modifying of the surface includes at least one of (i) biasing the selective portions of the surface, (ii) supplying the gas at a pressure below a predetermined pressure, or (iii) maintaining a pressure within the processing chamber at less than the predetermined pressure. During the atomistic adsorption, the surface of the substrate is exposed to the at least one of the ligand or the organic species. The at least one of the ligand or the organic species is void of a metal precursor and is selectively adsorbed to form a metal complex in the surface of the substrate. During the rapid thermal annealing, the heat source is pulsed on and off multiple times to remove the metal complex from the substrate.

In other features, the gas includes oxygen (O₂) or hydrogen (H₂). In other features, the ligand includes chlorine (Cl₂). In other features, the portions of the surface include (i) a bottom portion of a top layer in a hole of an intermediate layer of the substrate, and (ii) a top portion of the top layer disposed on the intermediate layer. In other features, the portions of the surface do not include a sidewall portion of the top layer disposed on a sidewall of the hole.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 a functional block diagram of an example of a substrate processing system incorporating a flash lamp and a rapid thermal pulse controller for performing rapid thermal pulse operations during metal ALE and metal atomic layer deposition (ALD) in accordance with the present disclosure;

FIG. 2 a functional block diagram of an example of a substrate processing system incorporating a laser, a lens circuit and a rapid thermal pulse controller for performing rapid thermal pulse operations during metal ALE and metal ALD in accordance with the present disclosure;

FIG. 3 is a side cross-sectional view of mirrors and a tele-centric lens assembly incorporated in the lens circuit of FIG. 2;

FIG. 4 is a metal ALE process diagram in accordance with the present disclosure;

FIG. 5A is a graph illustrating rapid thermal pulse cycles for removal of portions of a metal layer in accordance with the present disclosure;

FIG. 5B is a graph illustrating changes in reaction rates versus temperature for rapid thermal pulse cycles in accordance with the present disclosure;

FIG. 6 is a first example graph of etch rates for different oxidizers when hexafluoroacetylacetone (Hhfac) or molecular chlorine (Cl₂) is introduced according to an metal ALE process of the present disclosure;

FIG. 7 is a second example graph of etch rates for different oxidizers according to a metal ALE process of the present disclosure;

FIG. 8 is an example graph of oxygen concentration levels versus oxidation depths provided using different oxidizers in accordance with an embodiment of the present disclosure;

FIG. 9 is an example etch depth selectivity diagram for different patterns of introduced oxidizers in accordance with embodiment of the present disclosure;

FIG. 10 is a diagram illustrating iteratively performed rapid thermal pulse cycles for removal of portions of metal layers;

FIG. 11 illustrates a metal ALE method in accordance with the present disclosure;

FIG. 12 is functional block diagram of an example of a substrate processing system incorporating an acousto-optic modulator in accordance with an embodiment of the present disclosure;

FIG. 13 is a side view of mirrors and a substrate illustrating an incident angle in accordance with an embodiment of the present disclosure;

FIG. 14 is a functional block diagram of an example of a substrate processing system incorporating a optical beam folding assembly in accordance with an embodiment of the present disclosure;

FIG. 15 is a functional block diagram of an example of a substrate processing system incorporating circular-to-line beam shaping optics and at least one of a mirror or a polygon scanner in accordance with an embodiment of the present disclosure;

FIG. 16 is a cross-sectional view of a circular beam and a line beam in accordance with an embodiment of the present disclosure;

FIG. 17 illustrates a metal ALE method implementing non-rapid thermal pulsing and/or non-pulsed thermal annealing in accordance with an embodiment of the present disclosure;

FIG. 18 illustrates a back-end-of-line (BEOL) metal barrier ALE method in accordance with an embodiment of the present disclosure;

FIG. 19A is a cross-sectional view of a portion of a substrate in which a via is formed in accordance with an embodiment of the present disclosure;

FIG. 19B is a cross-sectional view of the portion of the substrate of FIG. 19A after removal of portions of a top layer using the BEOL metal barrier ALE method of FIG. 18; and

FIG. 19C is a cross-sectional view of the portion of the substrate of FIG. 19A after filling of a hole to form the via.

In the drawings, reference numbers may be reused to identify similar and/or identical elements.

### DETAILED DESCRIPTION

Traditional metal ALE (sometimes referred to as “thermal ALE”) is limited in speed, etch rate, surface adsorption coverage, selectivity and removal of certain metals from a substrate. Traditional metal ALE processes typically include preheating a substrate and introducing a metal precursor along with a ligand to modify a metal oxide surface of a substrate. The introduction of the metal precursor can result in metal contamination of the substrate. In addition, the surface modification performed can result in surface materials having low volatility, which negatively affects removal efficiency. Thus, traditional metal ALE processes have low etch rates (e.g., 0.1 Å/cycle). Also, the ligand may be introduced at temperatures between 300-400° C. At these temperatures, the amount of adsorbed ligand is low.

The examples set forth herein include performing metal ALE processes using organic vapors as ligands without metal precursors to provide metal complex layers. The organic vapors are introduced at low temperature (e.g., temperatures less than a boiling point of the metal complex layers), which increases the amount of organic vapor that is adsorbed. Pulsed thermal heating is used to remove the metal complex layers.

The ALE process allows the ligands to react with surface materials (e.g., metal oxide layers) of a substrate at low temperature to produce volatile materials. The volatile materials are removed using pulsed thermal heating. The metal ALE processes have short cycle times, are depth selective and produce efficient surface modification and removal. In some examples, the metal ALE is up to 100 times faster than traditional metal ALE processes. The metal ALE processes include ligand soaking of exposed surface material at low temperature. The soaked volatile surface material is exposed to high temperature to avoid re-deposition (side reactions).

The examples set forth herein include rapid thermal pulsing (RTP) systems for performing RTP cycles via heat sources to rapidly increase the temperature of upper and/or outer portions of substrates. By rapidly heating the upper and/or outer portions and not heating bases or bulk portions of the substrates, the upper and/or outer portions of the substrates are able to rapidly decrease in temperature after the heat sources are deactivated. Heating and cooling cycles may be performed very quickly as described below. Since the RTP heats a thin outer layer, thermal budget issues are avoided. In other words, thermal heating of a lower bulk portion of a substrate is substantially decreased or avoided. As an example, heating of the thin outer layer may be limited to a few hundred nanometers.

The RTP operations also enable performance of processes that were previously not performed due to sensitivity to thermal budget issues. As an example, isotropic and selective removal of certain upper and/or outer material layers from substrates may be performed. The upper and/or outer material layers may include film materials, which may include metals, metal oxides and/or metal nitrides. Some examples of metals that may be etched are tantalum (Ta), ruthenium (Ru), tungsten (W), cobalt (Co), platinum (Pt), aluminum (Al), barium (Ba), calcium (Ca), chromium (Cr), copper (Cu), erbium (Er), neodymium (Nd, nickel (Ni), palladium (Pd), strontium (Sr), tin (Sn), yttrium (Y), zinc (Zn), zirconium (Zr), hafnium (Hf), and titanium (Ti). Some examples of metal oxides that may be etched are aluminum oxide (Al₂O₃), hafnium oxide (HfO₂), zirconium oxide (ZrO₂), yitrium oxide (Y₂O₃), tin oxide (SnOₓ), and zinc oxide (ZnO). Some examples of metal nitrides that may be etched are titanium nitride (TiN), tantalum nitride (TaN), and aluminum nitride (AlN).

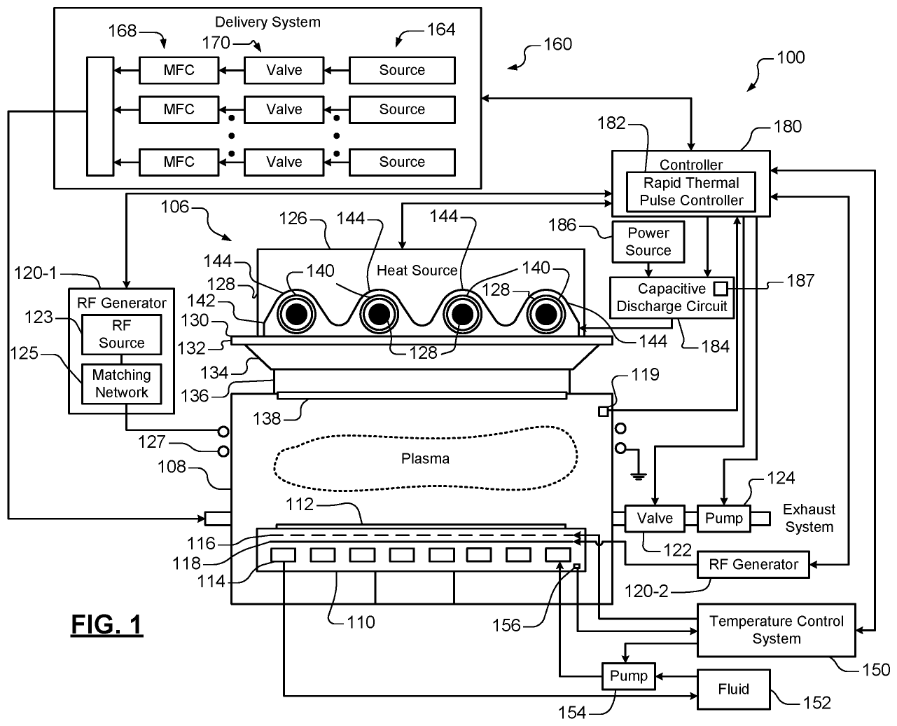

Referring now to FIG. 1, an example of a substrate processing system 100 that can be used is shown. While the substrate processing system 100 includes an inductively coupled plasma (ICP) source, other types of processing chambers and/or plasma sources (such as remote plasma sources) may be used. A remote plasma source may optionally be provided to utilize radicals. An example of another processing chamber is a remote plasma source connected chamber (or first chamber) that is connected to another processing chamber (or second chamber). The substrate processing system 100 includes an RTP system 106 and a processing chamber 108. The processing chamber 108 includes a substrate support 110 for supporting a substrate 112. The RTP system 106 rapidly and iteratively heats a surface and/or a portion of the substrate 112. In some examples, the substrate support 110 includes an electrostatic chuck or vacuum chuck. In some examples, the substrate support 110 is temperature controlled. For example, the substrate support 110 may include fluid channels 114 and/or heaters 116, which may be arranged in one or more zones. The substrate support 110 may further include an electrode 118.

One or more sensors 119 such as temperature and/or pressure sensors may be arranged in the processing chamber 108 to sense temperature and/or pressure, respectively. A valve 122 and pump 124 may be used to control pressure within the processing chamber 108 and/or to evacuate reactants from the processing chamber 108.

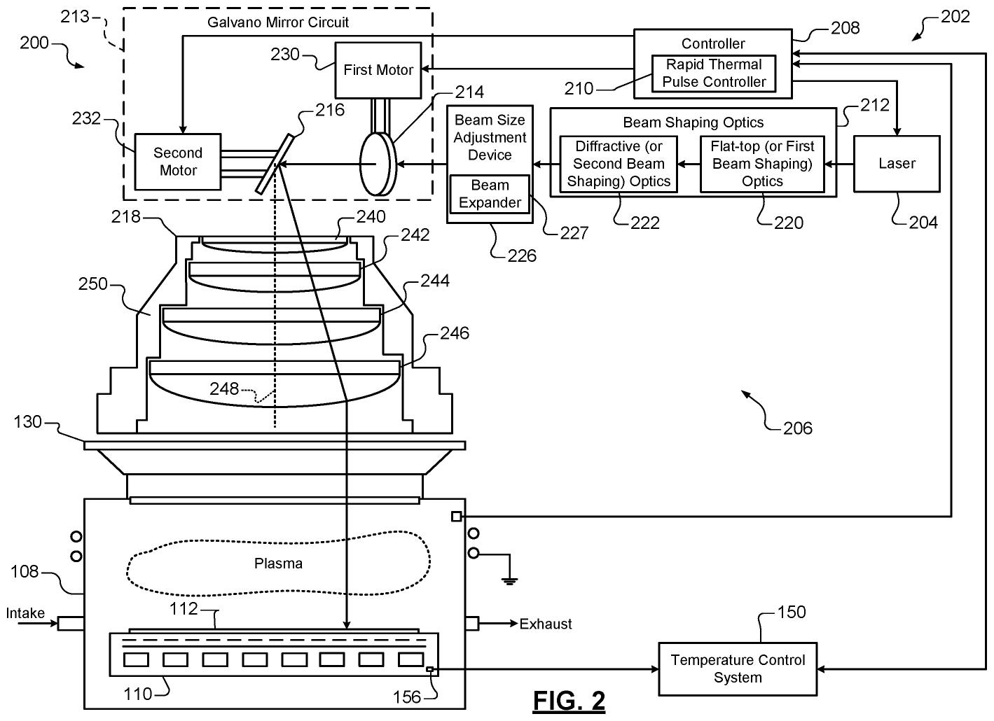

The RTP system 106 includes a heat source 126 that performs rapid thermal annealing of the substrate 112. This includes RTP via flash lamps 128. An example of another RTP system that is laser based is shown in FIG. 2. A window assembly 130 may be disposed between the heat source 126 and the processing chamber 108. The window assembly 130 includes a first (or dielectric) window 132, a reflector 134, a coupling member 136 and a second window 138. The first window 132 may be a quartz window. The reflector 134 may be formed of stainless steel and may be conical-shaped to direct thermal energy generated by the flash lamps 128 towards the substrate 112. The second window 138 may be a sapphire window. The coupling member 136 connects the reflector 134 to the processing chamber 108. In one embodiment, the reflector 134 is not included and the first window 132 is attached to the coupling member 136. The flash lamps 128 may be cylindrically-shaped and include respective cooling jackets 140 through which water and/or other cooling fluid may be circulated to cool the flash lamps 128. A reflector 142 having parabolic reflective portions 144 may be disposed on the first window 132. The reflector 142 may be formed of aluminum. The flash lamps 128 are disposed respectively in the parabolic reflective portions 144 between the reflector 142 and the first window 132.

A temperature control system 150 may be used to control a temperature of the substrate support 110 and the substrate 112. The temperature control system 150 may control supply of a fluid from a fluid source 152 via a pump 154 that is connected to the fluid channels 114. The temperature control system 150 may also control operation of the heaters 116. The temperature control system 150 may include one or more temperature sensors 156 to sense temperatures of one or more locations or zones of the substrate support 110.

A delivery system 160 includes one or more sources 164, one or more valves 106, one or more mass flow controllers 168 and a mixing manifold 170. The delivery system 160 selectively supplies gases, vapors, liquids, chemicals, plasma gas mixtures, carrier and/or inert gases, and/or purge gas mixtures to the processing chamber 108 during pretreatment, doping, passivation, surface modification, atomistic adsorption, annealing and/or purging.

An RF generator 120-1 includes an RF source 123 and a matching network 125 that outputs RF power to a coil 127, which surrounds an outer wall of the processing chamber 108. The RF generator 120-1 creates a magnetic field in the processing chamber 108 that strikes plasma. Another RF generator 120-2 may be used to supply an RF bias to the electrode 118 in the substrate support 110. A controller 180 communicates with the one or more sensors 119, the valve 122 and pump 124, the temperature control system 150, the heat source 126, the RF generators 120-1 and/or 120-2, and the delivery system 160 to control the process being performed.

The controller 180 may include a RTP controller 182, which controls a capacitive discharge circuit 184 to pulse the flash lamps 128. The capacitive discharge circuit 184 may receive power from a power source 186 and a control signal from the RTP controller 182. The capacitive discharge circuit 184 may charge capacitors (represented by box 187) when in an idle mode and may discharge the capacitors upon receiving a discharge signal from the RTP controller 182. The RTP controller 182 may perform RTP operations during metal ALE and/or metal ALD processes.

FIG. 2 shows an example of a substrate processing system 200 incorporating a RTP system 202 including a laser 204, a lens circuit 206 and a controller 208 with a RTP controller 210. The substrate processing system 200 may operate similar to the substrate processing system 100 of FIG. 1 and include portions of the substrate processing system 100 not shown in FIG. 2. The substrate processing system 200 includes the laser 204, the lens circuit 206, and the controller 208 instead of the heat source 126, the controller 180, and the capacitive discharge circuit 184. The laser 204 is a heat source that may be pulsed (or modulated) by the RTP controller 210 during RTP operations based on a control signal received from the RTP controller 210. This may occur during metal ALE and metal ALD processes.

The lens circuit 206 includes beam shaping optics 212, a Galvano mirror circuit 213 that includes a first mirror 214 and a second mirror 216, and a tele-centric lens assembly 218. The beam shaping optics 212 may include flat-top (or first beam shaping) optics 220 and diffractive (or second beam shaping) optics 222. The flat-top optics 220 are used to convert a laser beam received from the laser 204, where the laser beam has a Gaussian distribution, into a flat-top beam (e.g., a 2 centimeter (cm)×2 cm flat-top beam). A temperature profile of the laser beam is also Gaussian. An example of a flat-top optic is a “flywheel” optic.

The diffractive optics 222 convert the flat-top circular beam out of the flat-top optics 220 to a square beam. The square beam has a corresponding uniform temperature distribution on a substrate. This allows for a uniform thermal reaction and/or etch rate over the portion of a substrate (e.g., substrate 112) exposed to the square beam. Providing a square beam also provides a beam with a shape that matches a shape of a die being heated. The square beam may uniformly heat a surface or an upper portion of a selected die. The substrate 112 may be disposed on the substrate support in the processing chamber 108.

A beam size adjustment device 226 may be disposed between the beam shaping optics 212 and the first mirror 214. The beam size adjustment device 226 may adjust a size of the square beam to be greater than or equal to a size of a die on the substrate 112. The beam size adjustment device 226 may be motorized and include a beam expander 227. The beam expander 227 may perform magnification and increase a size of the laser beam.

The RTP controller 210 and the Galvano mirror circuit 113 may operate as a X-Y galvanometer scanning system. The first mirror 214 may be used to move the laser beam across a surface of the substrate 112 in a first (or X) direction. The second mirror 216 may be used to move the laser beam across the surface of the substrate in a second (or Y) direction. The controller 208 and/or the RTP controller 210 may move the mirrors 214, 216 via motors 230, 232.

The tele-centric lens assembly 218 may be referred to as a collimating assembly and includes a series of plano-convex lenses 240, 242, 244, 246. Although a particular number of plano-convex lenses are shown, a different number of plano-convex lenses may be included. The diameter of the plano-convex lenses 240, 242, 244, 246 increases the closer the plano-convex lens is to the window assembly 130, such that: a diameter of the lens 242 is larger than a diameter of the lens 240; a diameter of the lens 244 is larger than the diameter of the lens 242; and a diameter of the lens 246 is larger than the diameter of the lens 244. The plano-convex lenses 240, 242, 244, 246 are vertically aligned to have a common centerline 248. The plano-convex lenses 240, 242, 244, 246 are held in a fixed relationship within a mold 250. The plano-convex lenses 240, 242, 244, 246 direct the laser beam received from the second mirror 216 to be orthogonal to the surface of the substrate 112. As the laser beam is moved across the surface of the substrate 112, the tele-centric lens assembly 218 maintains the laser beam in an orthogonal relationship with the surface of the substrate 112.

As an example, the laser beam generated by the laser 204 may be 355 nm in diameter and may be pulsed every 80 picoseconds (ps). The RTP controller 210 may move the mirrors 214, 216 to perform 150 Hertz (Hz) scan across the surface of the substrate 112.

The substrate processing system 200 may include the temperature control system 150, which may be used to control a temperature of the substrate support 110 and the substrate 112. The temperature control system 150 may include the one or more temperature sensors 156 to sense temperatures of one or more locations or zones of the substrate support 110.

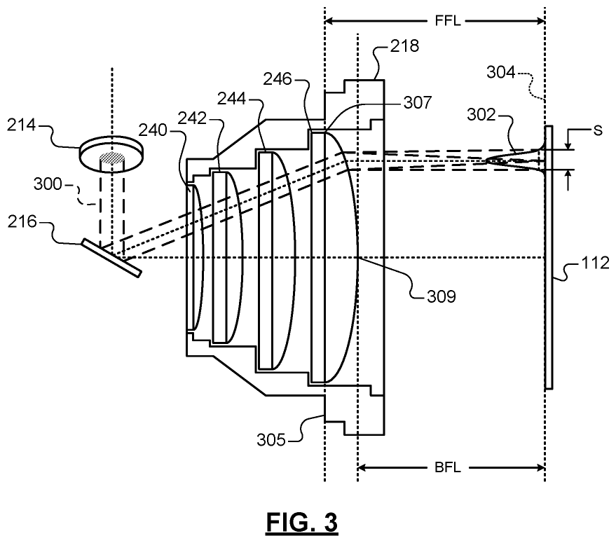

FIG. 3 shows a side cross-sectional view of the mirrors 214, 216 and the tele-centric lens assembly 218 of FIG. 2. The mirrors 214, 216 are shown and direct a laser beam 300 through the tele-centric lens assembly 218. The laser beam 300 is passed through the lenses 240, 242, 244, 246 from the smallest lens 240 to the largest lens 246. When the laser beam 300 is round and does not pass through the beam shaping optics 212 of FIG. 2, the laser beam has a Gaussian distribution as represented by curve 302 on an image plane 304 or surface of the substrate 112. When the laser beam 300 passes through the beam shaping optics 212, the laser beam is square shaped and has a spot with sides S.

The Galvano mirror circuit 213 of FIG. 2 provides a system including 2 mirrors for scanning a full field-of-view (FOV). As an example, the FOV may be greater than 300 mm×300 mm. In one embodiment, the lenses 240, 242, 244, 246 collectively have a low numerical aperture (less than a predetermined numerical aperture) and a focal column parameter (or beam perpendicularity parameter) within a predetermined range of being perpendicular relative to the image plane 304. The laser beam is provided perpendicular to the image plane without beam distortion at the image plane while beam uniformity and intensity is maintained. The laser beam may be focused on the image plane 304. In one embodiment, the pupil aperture or size of a side S of the beam spot is limited to 10-12 mm. The beam size adjustment device 226 of FIG. 2 may increase the size of the beam spot, such that S is 20-22 mm.

A flange focal length (FFL) and a back focal length (BFL) are shown. The FFL may be a distance from (i) an end of a flange 305 and/or a point 307 where the lens 246 begins to curve and protrude outward towards the image plane 304, and (ii) the image plane 304. The BFL may refer to a distance from (i) a point 309 on the lens 246 closest to the image plane 304, and (ii) the image plane 304.

The above-described examples of FIGS. 1-3 provide a flash lamp example and a laser beam example. The flash lamps may be modulated (or pulsed) every predetermined number of micro-seconds (e.g., every 300 μs) and the laser beam may be modulated (or pulsed) every predetermined number of pico-seconds (e.g., every 80 ps). The examples allow for performing a sequential thermal metal ALE or metal ALD process. As an example, a 100 μs pulsed light source may be used providing 8 Joules (J) of lamp power per centimeter squared (cm²) with a 1 Hz cycle. Greater than 50 cycles may be performed for a single recipe within a single processing chamber. A metal ALE process may be performed including atomistic and isotropic removal of material. These processes are efficiently performed while controlling substrate temperatures without thermal budget issues.

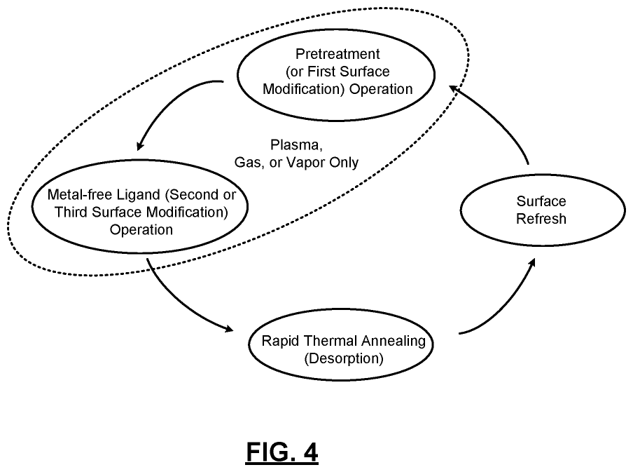

FIG. 4 shows a metal ALE process diagram illustrating a metal ALE process. The metal ALE process includes etching a metal, a metal oxide, a metal nitride and/or other material including a metal. The metal ALE process is a metal-free ligand process that includes performing atomistic adsorption without use of a metal precursor. The metal ALE process may include iteratively performing: (i) a first surface modification (or pretreatment) operation; (ii) a second surface modification (or atomistic adsorption) operation including a metal-free ligand and/or organic vapor; (iii) a RTP (or thermal removal) operation; and (iv) a surface refresh (or purge) operation. The metal-free ligand atomistic adsorption operation may be performed at temperatures less than a boiling point of metal complex materials formed as a result of performing the surface modification operations. The RTP may be used to remove films atomistically and isotropically without thermal budget issues, as compared to traditional continuous wave (CW) heating approaches. In one embodiment, thermal pulse durations are less than 3 ms in duration and increase surface substrate temperatures to approximately 500° C. to avoid thermal budget issues.

During pretreatment (or a first surface modification operation), molecular oxygen (O₂) plasma, ozone (O₃), hydrogen peroxide (H₂O₂), water vapor plasma, molecular hydrogen (H₂) plasma, molecular chlorine (Cl₂) plasma, ammonia (NH₃) plasma, and/or other gas may be supplied. During pretreatment, a plasma may be provided to modify a surface and/or portion of a substrate.

During the second surface modification operation, a metal-free ligand in the form of an organic gas or vapor is introduced. The metal-free ligand may include a reactive free ligand, such as hexafluroacetylacetone (Hhfac) and/or acetylacetone (Hacac), and/or other organic gas, vapor and/or reactant to be adsorbed into the surface and/or portion of the substrate. The metal-free ligand may include molecular chlorine (Cl₂), ethanol (EtOH), or other organic vapor. Other example ligands that may be used are trifluroacetic acid, acetic acid, acetonitrile, dimethylformamide, tetramethylethlyenediamine, tert-butyl isocyanide, tert-butylamine, dimethylamine, tert-butyl alcohol, and tert-butylthiol. Different variations of Hacac may be used including, for example, various compounds including two or more of carbon (C), fluorine (F), hydrogen (H), oxygen (O), sulfur (S), nitrogen (N), phosphorus (P), selenium (Se), and arsenic (As) elements. Other examples variations of Hacac that may be used are: acetylacetone; trifluoroacetylacetone; hexafluoroacetylacetone; dipivaloylmethane; pivaloyltrifluoroacetone; dibenzoylmethane; 4, 4, 4-trifluoro-1-phenyl-1,3-butanedione; 4,4-difluoro-1-phenyl-1,3-butanedione; 4,4,4-trifluoro-1-(2-thienyl)-1,3-butanedione; and 4,4,4-trifluoro-1-(2-furyl)-1,3-butanedione.

The portion of the substrate subjected to atomistic adsorption may be formed of a metal, a metal oxide, or a metal nitride. Some examples of metals that may be etched are tantalum (Ta), ruthenium (Ru), tungsten (W), cobalt (Co), platinum (Pt), aluminum (Al), barium (Ba), calcium (Ca), chromium (Cr), copper (Cu), erbium (Er, neodymium (Nd), nickel (Ni), palladium (Pd), strontium (Sr), tin (Sn), yttrium (Y), zinc (Zn), zirconium (Zr), hafnium (Hf), and titanium (Ti). Some examples of metal oxides (MOₓ) that may be etched are aluminum oxide (Al₂O₃), hafnium oxide (HfO₂), zirconium oxide (ArO₂), yitrium oxide (Y₂O₃), tin oxide (SnOₓ), and zinc oxide (ZnO). Some examples of metal nitrides that may be etched are titanium nitride (TiN), tantalum nitride (TaN), and aluminum nitride (AlN).

Subsequent to atomistic adsorption, the portion being removed may be a metal complex, for example including: a metal and a ligand, water, hydrogen, trimethylsilyl chloride, and/or other volatile and modified materials and/or substances.

In an embodiment, a predetermined number of cycles are performed to remove a predetermined amount of one or more layers of a substrate. As an example, a monolayer of an uppermost portion of a substrate may be removed per cycle of the metal ALE process. During the rapid thermal operation, a flash lamp assembly or a laser may be used as shown in FIGS. 1-2 and/or as described below.

The substrates may cool down during the surface refresh operations. The surface refresh operation may include the introduction of argon (Ar) gas. In one embodiment, active cooling is provided to cryogenically cool the substrates. This shortens the amount of time to cool down the substrates and allows for more cycles to be performed in a shortened period of time. Active cooling provides quick recovery without negatively affecting the base (or bulk) portion of the substrates.

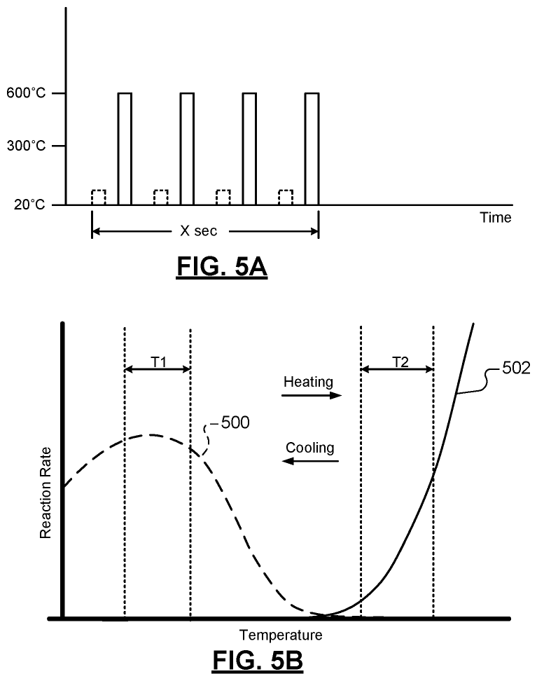

FIG. 5A shows an example temperature profile over time illustrating example rapid thermal pulses. In FIG. 5A, low temperature pulses and high temperature pulses are shown for illustration. The rapid thermal pulses provide isolated heating during independent operations to improve adsorption at low temperatures. This allows surface temperatures of a substrate to be controlled during the corresponding portion of an ALE process. The etch rate during rapid thermal pulsing is tunable based on a surface modification depth.

As an example, the low temperature pulses may be provided to increase temperatures of a portion of a substrate to 80° C. per cycle. The high temperature pulses may increase temperatures of the portion of the substrate to 600° C. per cycle. In one embodiment, the low temperature pulses increase temperatures of the portion of the substrate to 20-80° C. In one embodiment, the high temperature pulses increase temperatures of the portion of the substrate to 100-600° C. In another embodiment, the low temperature pulses are not provided. The portion of the substrate being heated is cooled down for example to a baseline temperature (e.g., 20° C.) between each consecutive pair of the low temperature pulses and/or the high temperature pulses. Multiple low temperature and/or high temperature pulses may be provided and the portion of the substrate being heated may cool down between sequential ones of the pulses over a predetermined number of seconds (shown as x seconds). As an example, multiple low temperature pulses and high temperature pulses may be provided over a 3-10 second long period.

The RTP described herein allows for heating and controlling substrate surface temperatures. Heating is provided to predetermined depths of a substrate in a controlled and tunable manner while providing atomistic reaction control. This may be accomplished by controlling the number, length, intensity, and frequency of the light (e.g., flash lamp or laser) pulses being generated. In one embodiment, a series of high temperature pulses are provided. In other embodiment, a series of low temperature pulses are provided. In another embodiment, a combination of low temperature and high temperature pulses are provided and the durations, intensities (or power levels) and frequencies of the pulses are controlled to provide a temperature depth profile across at least a portion of a surface of a substrate. By having multiple flash lamps as in the embodiment of FIG. 1, different temperature zones may be created by operating the flash lamps differently. For example, a first one or more of the flash lamps may be operated to provide a first series of pulses having a first set of one or more durations, one or more intensity levels (or power levels) and one or more frequencies and a second one or more of the flash lamps may be operated to provide a second series of pulses having a second set of one or more durations, one or more intensity levels (or power levels) and one or more frequencies.

FIG. 5B shows a reaction rate versus temperature for rapid thermal pulses similar to that shown in FIG. 5A. An example adsorption curve 500 and an example desorption (or etch) curve 502 are shown. For example, during atomistic adsorption of a metal free ligand, a corresponding metal layer may receive a low temperature pulse and/or may be cooling. An example time period T1, which may be less than 1 second in duration, is shown for a low temperature pulse. T1 may be the duration of the low temperature pulse. An example time period T2, which is less than 1 millisecond in duration, is shown for a high temperature pulse. T2 may be the duration of the high temperature pulse. The surface temperature may change quickly between low and high temperatures (e.g., less than 1 millisecond when heating and less than 1 second when cooling).

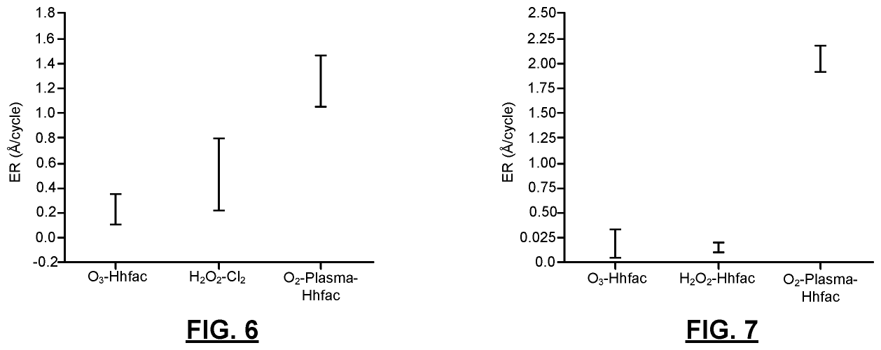

The following examples of FIGS. 6-7 are provided for a substrate having an upper physical vapor deposition (PVD) layer of titanium nitride (TiN). FIG. 6 shows a first example graph of etch rates for different oxidizers when hexafluoroacetylacetone (Hhfac) or molecular chlorine (Cl₂) is introduced according to a metal ALE process. Three example etch ranges are shown respectively for: ozone (O₃) with ligand hexafluoroacetylacetone (Hhfac; hydrogen peroxide (H₂O₂) with chloride; and oxygen (O₂) plasma with hexafluoroacetylacetone (Hhfac). This plot illustrates that the etch rate can be controlled based on the type of oxidizer selected. In an embodiment, the etch rate is primarily controlled by controlling an oxidation depth provided by introduction of an oxidizer. As shown, introduction of oxygen (O₂) may provide deeper oxidation for a higher etch rate when using Hhfac.

FIG. 7 shows a second example graph of etch rates for different oxidizers according to a metal ALE process. FIG. 7 is another example that etch rates can be adjusted based on the type of oxidizer used. Three example etch ranges are shown respectively for ozone (O₃) with ligand hexafluoroacetylacetone (Hhfac), hydrogen peroxide (H₂O₂) with ligand hexafluoroacetylacetone (Hhfac), and molecular oxygen (O₂) plasma with hexafluoroacetylacetone (Hhfac). All three example etch ranges are for the same ligand, but with different oxidizer pretreatment. The temperatures of the substrate associated with the graph of FIG. 7 are different than the temperatures of the substrate for the graph of FIG. 7. The temperature is one of several parameters that may be adjusted to change the etch rate. The etch rates may also be adjusted by adjusting RTP energy levels used during rapid thermal annealing.

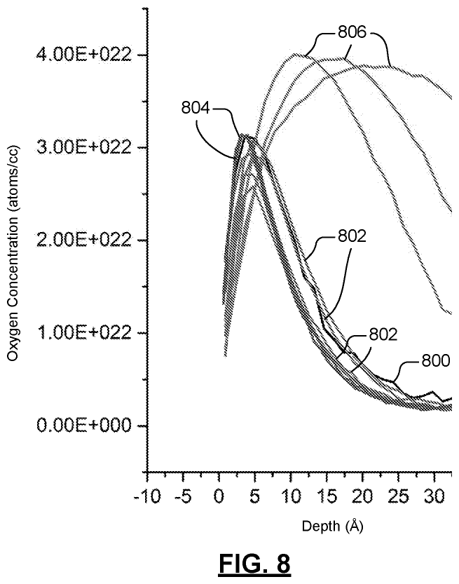

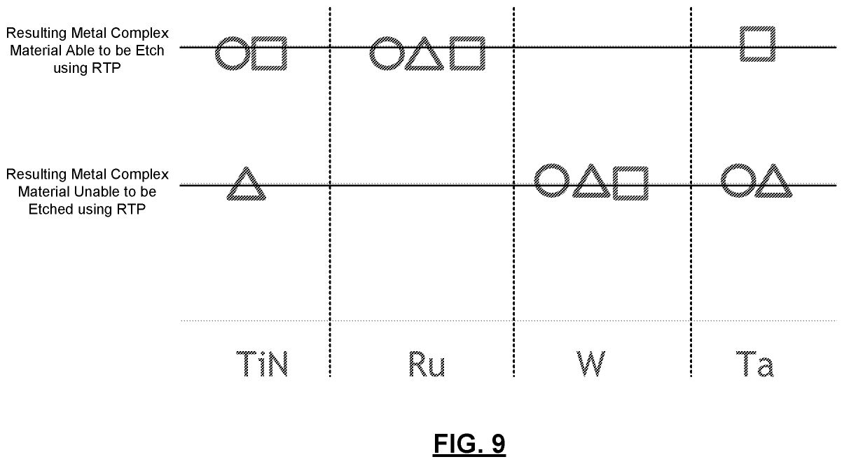

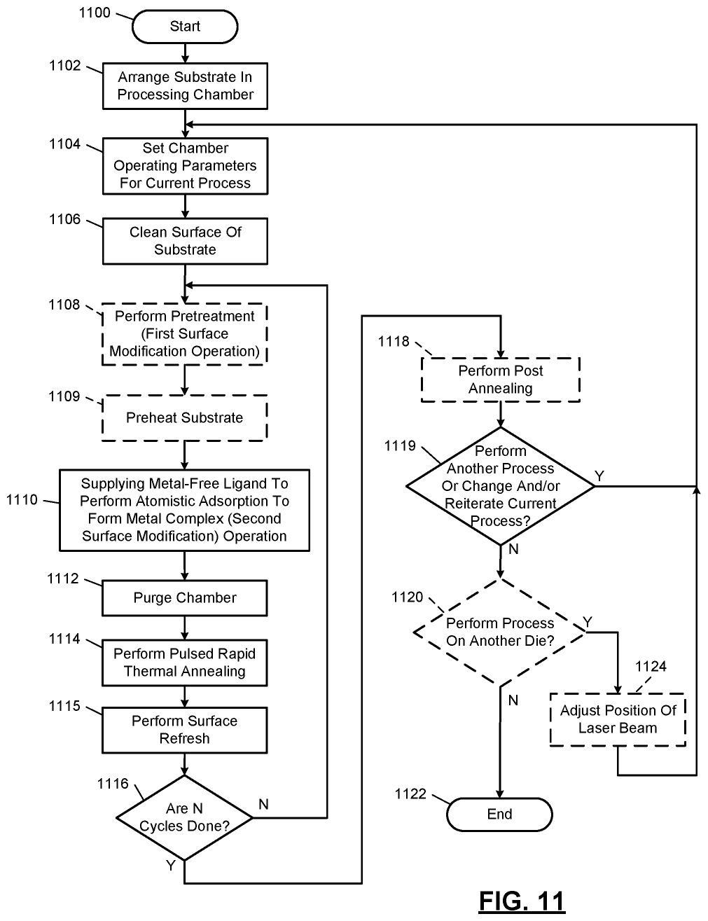

FIG. 8 shows an example graph of oxygen concentration levels versus oxidation depths for pre-treatment as performed in the metal ALE process of FIG. 4 and the method of FIG. 11. FIG. 8 shows: a plot 800 for unprocessed titanium nitride (TiN) layer of a substrate with little native oxidation due to exposure to room air, which includes a small percentage of oxygen; 4 plots 802 for ozone (O₃), where each of the 4 plots is associated with a different amount of heating; 2 plots 804 for hydrogen peroxide (H₂O₂), where each of the 2 plots is associated with a different amount of heating; and 3 plots 806 for molecular oxygen (O₂), where plasma each of the 3 plots is associated with a different amount of heating. As can be seen the amount and/or depth of oxygen adsorption may also be selectively controlled by controlling selection of the oxidizer used. By tuning the oxidation depth, the etch rate is also adjusted. The etch rate is related to the oxidation depth. As the oxidation depth increases, the etch rate also increases. In the example shown, the oxidation depth of hydrogen peroxide (H₂O₂) is less than the oxidation depth for ozone (O₃), which is less than the oxidation depth for molecular oxygen (O₂) plasma. Also, the more heating (or pre-heating), the higher the temperature of the substrate and the deeper the oxidation. The temperatures are between an ambient temperature and 200° C. As can be seen by the curves, the oxygen concentrations increase to a peak and then decrease with increasing depth.

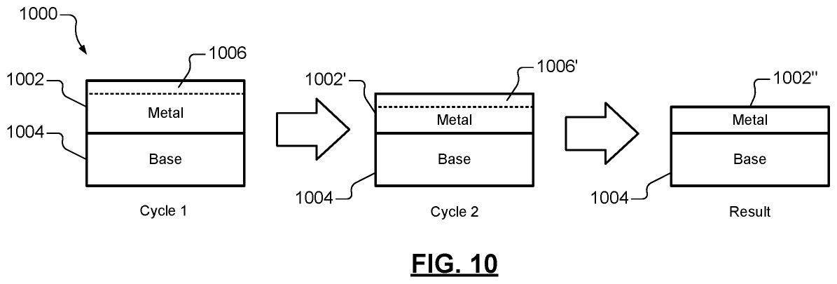

FIG. 9 shows an example etch depth selectivity diagram for different patterns of introduced oxidizers. Different patterns of oxidizers may be introduced to control etch depths and etch rates. Multiple cycles of the metal ALE process of FIG. 4 may be performed, where each cycle includes introducing one or more surface modification materials to perform a surface modification. Two rows of different patterns are shown as examples for different materials to be etched. The first row provides example patterns that allow for etching of the corresponding materials using RTP. The second row provides examples of patterns for which etching is unable to be performed for the corresponding materials using RTP. The example diagram also includes four columns for four materials being etched, the first material including titanium nitride TiN, the second material including ruthenium Ru, a third material including tungsten W, and a fourth material tantalum Ta.

The rows and columns provide cells, where each cell includes 0, 1, 2, or 3 symbols in a particular order. The symbols include a circle, a square and a triangle. The circle refers to introducing molecular oxygen (O₂) plasma and the ligand Hhfac followed by flash lamp heating. The triangle refers to introducing ozone O₃ gas) followed by flash lamp heating. The square refers to introducing molecular oxygen (O₂) plasma and molecular chlorine (Cl₂) followed by flash lamp heating. Although FIG. 9 shows use of certain gases, plasmas, and ligands, any types of gases, plasmas, ligands and/or other organic gases and/or vapors disclosed herein may be used. Similarly, although a certain types of heating and certain patterns of particular cycles are shown, other types of heating disclosed herein and any number of cycles may be performed in various orders.

FIG. 10 shows a diagram illustrating iteratively performed rapid thermal pulse cycles for removal of portions of a metal layer from a portion of a substrate. A stack of layers 1000 is shown from which portions are removed during each cycle. FIG. 10 is shown for example purposes only. Although top layers are shown as being modified and removed, the sides of the top layers may also be removed. Sides of the metal layers may be modified and removed without modifying and removing the top layers when a mask is disposed on the metal layers. The stack of layers 1000 includes an upper metal layer 1002 and a base layer 1004, which may include one or more layers. The upper metal layer 1002 includes a modified surface layer (or upper monolayer) 1006 including a metal, a metal oxide or a metal nitride that has been modified as described herein to be removed using RTP. The modified surface layer 1006 is removed during each cycle of the corresponding RTP process. For example, during a first cycle, the modified surface layer 1006 is removed from the metal layer 1002 to provide the metal layer 1002′. During a second cycle, a modified surface layer 1006′ is removed from the metal layer 1002′ to provide the metal layer 1002″.

The systems disclosed herein may be operated using numerous methods, example methods are illustrated in FIGS. 11, 17 and 18. FIG. 11 shows a metal ALE method implementing RTP as described herein. The metal ALE method may include the metal ALE process of FIG. 4, which may be iteratively performed, where each iteration is referred to as a cycle. Although the following operations are primarily described with respect to the implementations of FIGS. 1-2 and 4, the operations may be easily modified to apply to other implementations of the present disclosure. The operations may be iteratively performed. Certain operations, shown with dashed lines in FIG. 11, may not be performed or may be skipped for a current cycle.

The method may begin at 1100. At 1102, a substrate (e.g., the substrate 112 of FIGS. 1 and 2 and/or a 300 mm diameter substrate) is arranged in a processing chamber. At 1104, chamber operating parameters such as substrate support temperatures, chamber pressures, RF power and bias power levels, and gas flow rates are set. During operation 1104, types of gases, vapors, liquids, ligands, organic vapors, etc. to be introduced during the following operations 1108, 1110. During operation 1104, volumes, flow rates, and/or pressures of the gases, vapors, liquids, ligands, organic vapors, etc. introduced during the operations 1108, 1110 may also be determined. Energy levels for operation 1114 may also be selected. The stated operating parameters may be selected and/or adjusted to adjust etch rates per cycle of the metal ALE process being performed. The etch rates are tunable. In one embodiment, the gases, vapors, liquids, plasmas, and/or chemicals used to perform surface modification operations are selected and corresponding volumes, amounts, pressures, flow rates and start, end and/or duration times of the flow of the gases, vapors, liquids, plasmas and/or chemicals are determined. This may include durations: during which flow is stopped; durations that a substrate is exposed to one or more gases, vapors, liquids, plasmas and/or chemicals; purge times; and/or other related timing. Temperature levels and RTP energy levels and corresponding timing may also be determined. The stated information may be determined for each cycle being performed.

At 1106, a surface of the substrate is cleaned. As an example the substrate may include an upper (or top) layer that is disposed on a base layer. The upper layer may include or consist of a metal, a metal oxide or a metal nitride. The upper surface of the upper layer may be cleaned.

At 1108, pretreatment may be performed including exposing one or more surfaces and/or layers of the substrate that include a metal, a metal oxide or a metal nitride with, for example, molecular oxygen (O₂) plasma, ozone (O₃), hydrogen peroxide (H₂O₂), water vapor plasma, hydrogen (H₂) plasma, molecular chlorine (Cl₂) plasma, hydrazine (N₂H₄), ammonia (NH₃) plasma, and/or other gas. The surface modification may include a non-plasma process, such as flow of chemicals, hydrogen peroxide (H₂O₂) vapor, water (H₂O) vapor, hydrazine (N₂H₄), and/or other chemical reactant. In another embodiment, the surface modification includes a plasma process, such as flow of molecular oxygen (O₂) plasma, molecular hydrogen (H₂) plasma, an ammonia (NH₃) plasma, a water (H₂O) plasma, and/or other plasma. As an example, this may include supplying O₂ plasma to convert TiN (Ti³⁺) to TiO₂ (Ti⁴⁺), which may occur at room temperature or at other temperatures. Operation 1108 may be performed to convert a metal to a metal oxide or a metal halide. This operation may be performed for de-chlorination and surface activation. As an example, a plasma gas mixture including hydrogen (H₂) gas or ammonia (NH₃) gas species is supplied to the processing chamber. In one embodiment, surface modification is performed without plasma, but by using gases having a preselected chemistry.

At 1109, the substrate is optionally preheated. This may include increasing temperature of the substrate support and/or temperature within the corresponding processing chamber as described above. As an example, the temperature of the substrate, substrate support, and/or interior of the processing chamber may be increased to a predetermined temperature (e.g., 200° C.). In an embodiment, operation 1109 is not performed and the substrate is maintained at a room temperature. In one embodiment, the temperature of the substrate, substrate support and/or interior of the processing chamber are at temperatures greater than or equal to a room temperature and less than a boiling point of a complex metal to be formed as a result of performing the following operation 1110.

At 1110, atomistic adsorption is performed including introduction of one or more reactive free ligands, such as hexafluroacetylacetone Hhfac and/or acetylacetone Hacac, and/or introduction of one or more other organic gases, vapors and/or reactants to be adsorbed into the substrate. The metal-free ligand may include molecular chlorine (Cl₂), ethanol (EtOH), and/or other organic vapor. In an embodiment, the metal-free ligand is Cl₂. This operation includes converting one or more upper and/or outer surfaces/layers of the substrate that was modified at 1108 into a layer having a metal complex. Operation 1110 may occur at temperatures, for example, greater than or equal to a room (or ambient) temperature and less than a boiling point of the metal complex. The one or more ligands introduced may be selected based on the metal, metal oxide, and/or metal nitride being etched, the pre-treatment performed, the temperature of the surface/layer being etched, the energy level used for etching, etc. This enables precise and highly selective etching including selective etch depths and etch rates for surfaces having different metals and/or metal compounds.

At 1112, the corresponding process chamber is purged of gases. At 1114, pulsed rapid thermal annealing is performed using, for example, flash lamps, a laser or other suitable lamps (e.g., infrared lamps) capable of being rapidly pulsed as described herein. In an embodiment, flash lamps are utilized providing a predetermined amount of thermal energy (e.g., 7 Joules (J) or 11 J). In another embodiment, pulsed laser is utilized.

At least operations 1108-1115 may be iteratively performed including modulating surface or upper portion temperatures of the substrate. The temperature of the surface or upper portion may be modulated multiple times in a single second. Pulsed rapid thermal annealing is performed at 1114 for desorption/removal purposes. This may include generating one or more thermal energy pulses to heat the modified portion of the substrate. Temperatures may be increased to evaporate certain molecules. Rapid thermal pulsing enables a clean reaction at surface of substrate, which frees the metal complex from the substrate.

As an example, a substrate may have a metal oxide layer including hafnium oxide, which is to be etched. At 1108, chlorination may be performed including introducing a chloride plasma and/or gas to convert HfO₂ to HfCl₄. Then at 1110, an organic gas, compound, and/or ligand, such as N, N-dimethytrimethylsilylamine (TMSDMA) or Hhfac may be introduced. At 1114, a metal dimethylamidos (e.g., metal-dimethylamine (Hf(DMA)₄)) and a highly volatile liquid (e.g., trimethylsilyl chloride TMSCl) may be removed if TMSDMA or the like was introduced at 1110. Hf(DMA)₄ and TMSCl may be removed if TMSDMA was introduced at 1110. Metal dimethylamidos are volatile and may be used as a vapor precursor. The described method may be performed to remove high boiling point halides, such as HfCl₄ (or metal chloride), by converting the high boiling point metal halide to a volatile organometallic compounds and an organosilicon compound (or volatile liquid), At 1114, Hf(hfac)₄ and HCl may be removed if Hhfac was introduced at 1110.

As another example, a substrate may have a metal layer or a metal oxide layer, such as a layer of hafnium or a layer of hafnium oxide, which is to be etched. At 1108, an oxygen plasma may be introduced followed by at 1110 an introduction of Hhfac. At 1114, Hf(hfac)₄ and H₂O may be removed.

As yet another example a substrate may have a metal layer or a metal oxide layer, such as a layer of hafnium or a layer of hafnium oxide, which is to be etched. At 1108, hydrogen plasma and optionally oxygen plasma may be introduced followed by at 1110 an introduction of Hhfac. At 1114, Hf(hfac)₄, H₂O and H₂ may be removed.

No inorganic salt or additional metal complex is produced when performing the above stated operations. An additional metal complex can be produced when, for example, a metal precursor is introduced. The above operations do not include introduction of a metal precursor. Incomplete organic residual may be cleaned easily by introducing hydrogen plasma or oxygen plasma in a surface refresh operation, such as at 1115.

A base and/or bulk of the substrate is maintained at or below a predetermined temperature (e.g., less than or equal to 20° C.) during operation 1114. RTP enables one processing chamber configuration to be used with high throughput. Multiple processing operations may be performed in the single processing chamber. As another example, each of the pulses may be 0.1 millisecond (ms) in length and a temperature of a surface and/or a portion of the substrate may be increased up to 1000° C.

In some examples, each of the flash lamp pulses provides 5 J/cm² (i.e., energy per unit area of the substrate) to 80 J/cm². In some examples, each of the laser pulses provides 5 mJ/cm² to 80 mJ/cm². In some examples, the annealing is performed during a predetermined period in a range from 0.1 ms to 20 ms. In one embodiment, the flash lamp is used with pulse durations of 1 ms or the laser is used with pulse durations of 1 picosecond (ps) to heat the surface or upper portion of the substrate from an initial temperature to greater than 500° C. and then cooled back down to the initial temperature in less than 1 second (s).

Operations 1108, 1110, 1114 allow for controllable atom by atom removal of a surface and/or upper layer of the substrate that was modified during operations 1108 and 1110. The rapid heating performed at 1114 provides an isotropic reaction without use of plasma. In addition, the claimed heating allows for rapid cool down, which also prevents thermal budget issues.

At 1115, the surface of the substrate may be refreshed by purging the process chamber with a purge gas (e.g., argon (Ar) gas) to perform ion bombardment and remove the modified portion(s) of the substrate. In one embodiment, the processing chamber is purged between one or more consecutive pairs of provided rapid thermal pulses. In an embodiment, the gases are purged from the processing chamber between each consecutive pair of pulses. This enables performance of multiple plasma and/or gas phase processes within the processing chamber. In an embodiment, substrate support cooling is provided during and/or subsequent to pulsed rapid thermal annealing to aid in maintaining temperatures of the base and/or bulk of the substrate during pulsed rapid thermal annealing and to aid in rapid cooling of the substrate subsequent to performing pulsed rapid thermal annealing.

At 1116, the controller 180 or 208 and/or rapid thermal pulse controller 182 or 210 determines whether N cycles have been completed, where N is an integer greater than or equal to 1. If N cycles have been completed, operation 1118 is performed, otherwise operation 1108 is performed. At 1118, the controller 180 or 210 may optionally perform a second (or post) annealing operation. At 1119, the controller 180 or 210 may determine, for a current die, whether to perform another process and/or whether to change and/or reiterate a current process. If another process is to be performed, operation 1104 may be performed, otherwise operation 1120 may be performed when a laser and a lens circuit is utilized as in the embodiment of FIG. 2. If flash lamps are used as in the embodiment of FIG. 1, the method may end at 1122 when another process or a change in a current process is not performed. If a process is to be performed on another die, operation 1124 is performed, otherwise the method may end at 1122.

At 1124, the controller 208 moves the mirrors 214, 216 to change an image plane position of a laser beam to be over a different die of the substrate 112. As an example, a 2 cm×2 cm laser beam may be moved from being over a first die to being over a second die. The described method may be iteratively performed to scan the laser beam over tens to hundreds of dies on the substrate. Movement of the mirrors 214, 216 may be synchronized with a pulsing repetition rate of the laser 204 to provide one or more shots per die.

The above-described operations are meant to be illustrative examples. The operations may be performed sequentially, synchronously, simultaneously, continuously, during overlapping time periods or in a different order depending upon the application. Also, any of the operations may not be performed or skipped depending on the implementation and/or sequence of events.

Although the method of FIG. 11 is described for performing metal ALE using the systems of FIGS. 1-2, the systems of FIGS. 1-2 may be used to perform metal ALD. The heat sources, such as the flash lamps and the laser, may be used to grow monolayers on substrates. For example, RTP may be provided prior to and/or during deposition operations and material may be deposited (or grown) rather than removed. Different gases may be provided and maintained in a corresponding processing chamber during metal ALD to allow for growth of the monolayers.

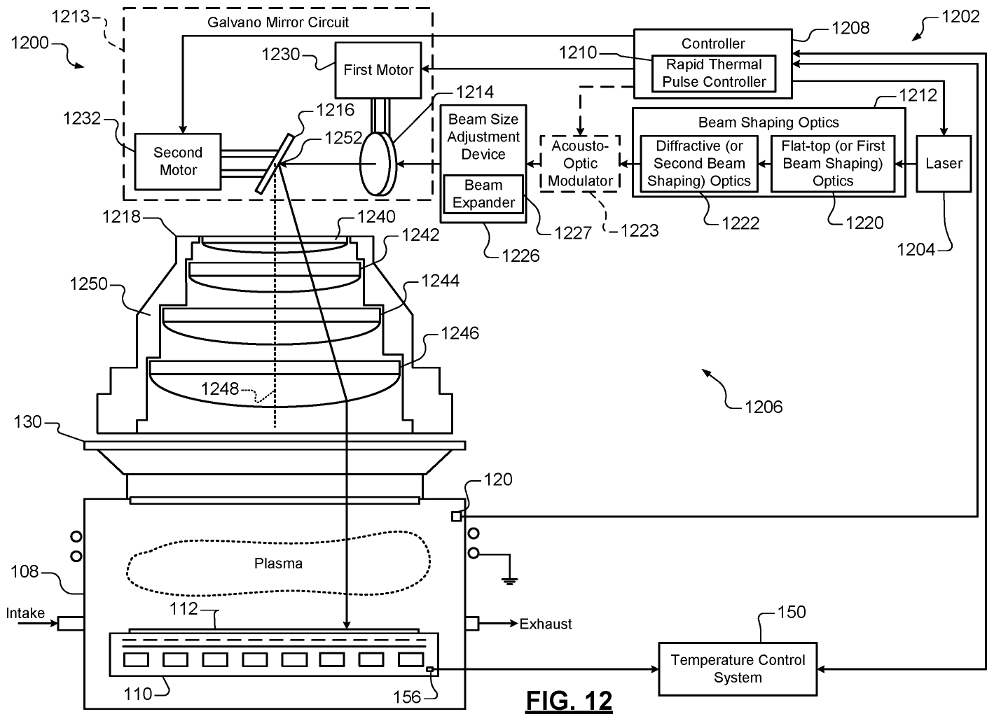

FIG. 12 shows an example of a substrate processing system 1200 incorporating a RTP system 1202 including a laser 1204, a lens circuit 1206 and a controller 1208 with a RTP controller 1210. The substrate processing system 1200 may operate similar to the substrate processing system 200 of FIG. 2. The laser 1204 is a heat source that may be pulsed (or modulated) by the RTP controller 1210 during RTP operations based on a control signal received from the RTP controller 1210. This may occur during metal ALE and metal ALD processes.

The lens circuit 1206 includes beam shaping optics 1212, a Galvano mirror circuit 1213 that includes a first mirror 1214 and a second mirror 1216, and a tele-centric lens assembly 1218. The beam shaping optics 1212 may include flat-top (or first beam shaping) optics 1220 and diffractive (or second beam shaping) optics 1222. The flat-top optics 1220 are used to convert a laser beam received from the laser 1204, where the laser beam has a Gaussian distribution, into a flat-top beam (e.g., a 2 centimeter (cm)×2 cm flat-top beam). A temperature profile of the laser beam is also Gaussian. The diffractive optics 1222 convert the flat-top circular beam out of the flat-top optics 1220 to a square beam. The square beam has a corresponding uniform temperature distribution on a substrate. The substrate 112 may be disposed on a substrate support (e.g., the substrate support 110 of FIG. 1).

The laser 1204 may be operated in a pulse mode or a continuous wave (CW) mode. During the pulse mode, the output of the beam shaping optics 1212 may be provided directly to the beam size adjustment device 1226. During the pulse mode, the RTP controller 1210 controls a pulse rate of the laser beam, such that pulse duration is in a pico-second or a nanosecond range. An acousto-optic modulator 1223 may be included when the laser 1204 is being operated in the CW mode and be controlled by the RTP controller 1210. In one embodiment, the RTP controller 1210 generates a radio frequency (RF) control signal, which is provided to the acousto-optic modulator 1223. The RF control signal is provided to control a change in a refractive index of a crystal of the acousto-optic modulator 1223. The refractive index of the crystal changes based on a frequency of the RF control signal. The laser beam provided from the beam shaping optics 1212 to the acousto-optic modulator 1223 is deflected by the crystal based on a frequency of the RF signal. The crystal performs as a laser shutter that permits or prevents passage of the laser beam to the beam size adjustment device 1226 and/or the first mirror 1214. In one embodiment, the RTP controller 1210 controls the frequency of the RF control signal, such that the continuous wave laser beam out of the beam shaping optics 1212 is effectively pulsed (or modulated) by the acousto-optic modulator 1223. The laser beam is pulsed, such that a period of each pulse is in a micro-second or a millisecond range. As a result, use of the acousto-optic modulator 1223 allows for pulsed laser beam generation having longer duration pulses for increased heating per pulse.

The beam size adjustment device 1226 may be disposed between the beam shaping optics 1212 and the first mirror 1214. In an embodiment, the beam size adjustment device 1226 adjusts a size of the square beam to be greater than or equal to a size of a die on the substrate 112. The beam size adjustment device 1226 may be motorized and include a beam expander 1227.

The RTP controller 1210 and the Galvano mirror circuit 1213 may operate as a X-Y galvanometer scanning system. The first mirror 1214 may be used to move the laser beam across a surface of the substrate 112 in a first (or X) direction. The second mirror 1216 may be used to move the laser beam across the surface of the substrate in a second (or Y) direction. The controller 1208 and/or the RTP controller 1210 may move the mirrors 1214, 1216 via motors 1230, 1232.

The tele-centric lens assembly 1218 may include a series of plano-convex lenses 1240, 1242, 1244, 1246. Although a particular number of plano-convex lenses are shown, a different number of plano-convex lenses may be included. The diameter of the plano-convex lenses 1240, 1242, 1244, 1246 increases the closer the plano-convex lens is to the window assembly 130, such that: a diameter of the lens 1242 is larger than a diameter of the lens 1240; a diameter of the lens 1244 is larger than the diameter of the lens 1242; and a diameter of the lens 1246 is larger than the diameter of the lens 1244. The plano-convex lenses 1240, 1242, 1244, 1246 are vertically aligned to have a common centerline 1248. The plano-convex lenses 1240, 1242, 1244, 1246 are held in a fixed relationship within a mold 1250. The plano-convex lenses 1240, 1242, 1244, 1246 direct the laser beam received from the second mirror 1216 to be orthogonal to the surface of the substrate 112. As the laser beam is moved across the surface of the substrate 112, the tele-centric lens assembly 1218 maintains the laser beam in an orthogonal relationship with the surface of the substrate 112.

As an example, a laser beam out of the beam shaping optics 1212, the acousto-optic modulator 1223 and/or the beam size adjustment device 1226 may be focused at the a center 1252 of the second mirror 1216 and then be directed through the tele-centric lens assembly 1218, where the laser beam is collimated and provided to the substrate 112. Focusing the laser at an input pupil of the second mirror (or lens) 1216 aids in providing a collimated beam at an upward facing surface of the substrate 112.

As an example, the laser beam generated by the laser 1204 may be 355 nm in diameter. The laser 1204 may operate in the pulse mode or the CW mode. The beam shaping optics 1212, the beam size adjustment device 1227, and the tele-centric lens assembly 1218 may generate a 2 centimeter by 2 centimeter square beam that is received at the substrate 112. The RTP controller 1210 may move the mirrors 1214, 1216 to perform a 200 Hz scan across a surface of the substrate 112. The RTP controller 1210 may scan over all dies and/or an upward facing surface area (e.g., for a 300 mm diameter substrate, the 2.83×10⁵ mm upward facing surface area of the substrate) within a 1 second period of time. This may include scanning over, for example, 160 dies of the substrate within 1 second. The scanning includes moving the laser beam from die-to-die and heating each die for a predetermined period of time (e.g., an overall period of one or more pulses of the laser beam).

The substrate processing system 1200 may include the temperature control system 150, which may be used to control a temperature of the substrate support 110 and the substrate 112. The temperature control system 150 may include the one or more temperature sensors 156 to sense temperatures of one or more locations or zones of the substrate support 110.

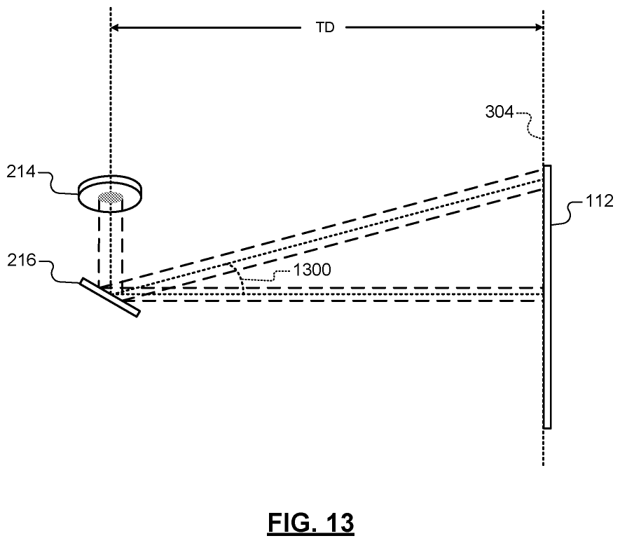

A tele-centric lens assembly, as shown in FIG. 3, can be expensive to implement. A laser beam can be collimated without use of a tele-centric lens assembly. As an example and referring to FIGS. 3 and 13, the tele-centric lens assembly 218 of FIG. 3 may be removed and the mirror 216 is moved away from the image plane 304 in order to collimate the laser beam. In order to collimate the laser beam and minimize the angles at which light rays are directed at the substrate 112 (or angles away from a direction orthogonal to the image plane 304), a transmission distance TD between the mirror 216 and the image plane 304 is maximized and/or set above a predetermined minimum distance. If the light rays are directed in a direction orthogonal to the image plane 304, then an ideal laser beam condition exists for etch rate uniformity across a surface of the substrate 112. If the light rays are directed at angles within a small predetermined range of being orthogonal (e.g., 90°±3°), then the laser beam is sufficiently collimated to provide surface etching uniformity above a predetermined minimum uniformity level. To direct the light rays of a laser beam, such that angles of the lights rays are within the predetermined range, the distance TD is set greater than or equal to a predetermined length (e.g., 3 meters). The larger the distance TD, the smaller the angles and thus the more collimated the laser beam. FIG. 13 shows when (i) the laser beam is directed at a center of the substrate 112, and (ii) when the laser beam is directed towards an edge of the substrate 112. An incident angle 1300 between these two transmissions decreases the further the mirror 216 is from the image plane 304.

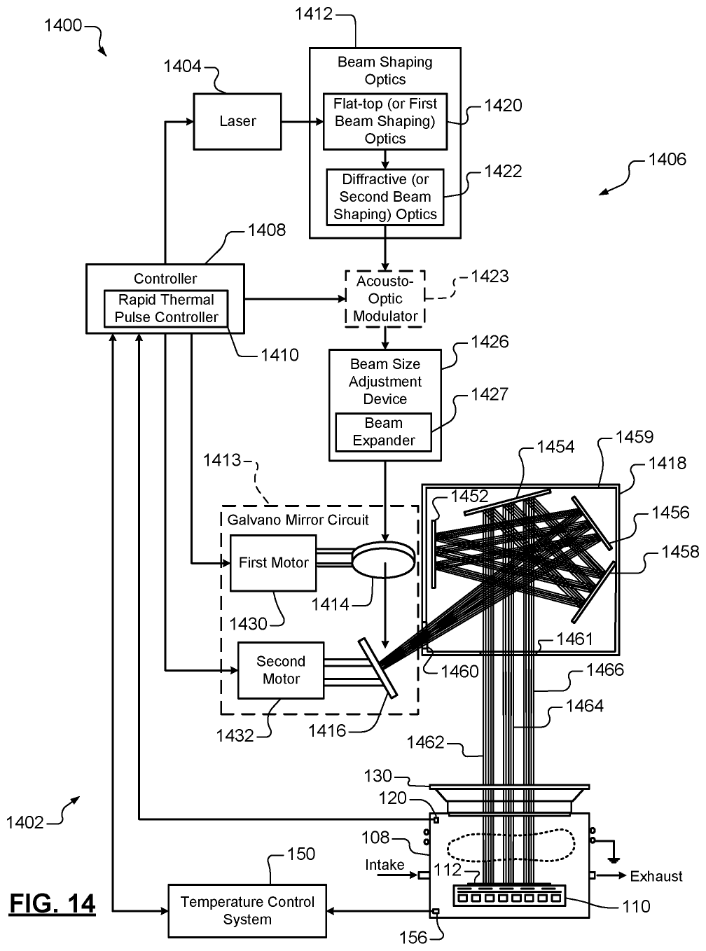

In order to reduce the distance between the mirror 216 and at the same time collimate the laser beam, an optical beam folding assembly may be incorporated between the mirror 216 and the image plane 304. The optical beam folding assembly improves tele-centricity. An example of this is shown in FIG. 14. FIG. 14 shows an example of a substrate processing system 1400 incorporating a RTP system 1402 including a laser 1404, a lens circuit 1406 and a controller 1408 with a RTP controller 1410. The substrate processing system 1400 may operate similar to the substrate processing system 200 of FIG. 2 and the substrate processing system 1200 of FIG. 12. The laser 1404 is a heat source that may be pulsed (or modulated) by the RTP controller 1410 during RTP operations based on a control signal received from the RTP controller 1410. This may occur during ALE and ALD processes.

The lens circuit 1406 includes beam shaping optics 1412, a Galvano mirror circuit 1413 that includes a first mirror 1414 and a second mirror 1416, and an optical beam folding assembly 1418. The beam shaping optics 1412 may include flat-top (or first beam shaping) optics 1420 and diffractive (or second beam shaping) optics 1422. The flat-top optics 1420 are used to convert a laser beam received from the laser 1404, where the laser beam has a Gaussian distribution, into a flat-top beam (e.g., a 2 centimeter (cm)×2 cm flat-top beam). A temperature profile of the laser beam is also Gaussian. The diffractive optics 1422 convert the flat-top circular beam out of the flat-top optics 1420 to a square beam. The square beam has a corresponding uniform temperature distribution on a substrate 112. The substrate 112 may be disposed on the substrate support in the processing chamber 108.

The laser 1404 may be operated in a pulse mode or a continuous wave (CW) mode. During the pulse mode, the output of the beam shaping optics 1412 may be provided directly to the beam size adjustment device 1426. During the pulse mode, the RTP controller 1410 may control a pulse rate of the laser beam, such that pulse duration is in a pico-second or a nanosecond range. An acousto-optic modulator 1423 may be included when the laser 1404 is being operated in the CW mode. The acousto-optic modulator 1423 may be controlled by the RTP controller 1410. In one embodiment, the RTP controller 1410 generates a RF control signal, which is provided to the acousto-optic modulator 1423. The RF control signal is provided to control a change in a refractive index of a crystal of the acousto-optic modulator 1423. The refractive index of the crystal changes based on a frequency of the RF control signal. The laser beam provided from the beam shaping optics 1412 to the acousto-optic modulator 1423 is deflected by the crystal based on a frequency of the RF signal. The crystal performs as a laser shutter that permits or prevents passage of the laser beam to the beam size adjustment device 1426 and/or the first mirror 1414. In one embodiment, the RTP controller 1410 controls the frequency of the RF control signal, such that the continuous wave laser beam out of the beam shaping optics 1412 is effectively pulsed (or modulated) by the acousto-optic modulator 1423. The laser beam is pulsed, such that a period of each pulse is in a micro-second or a millisecond range. As a result, use of the acousto-optic modulator 1423 allows for pulsed laser beam generation having longer duration pulses for increased heating per pulse.

The beam size adjustment device 1426 may be disposed between the beam shaping optics 1412 and the first mirror 1414. The beam size adjustment device 1426 may adjust a size of the square beam to be greater than or equal to a size of a die on the substrate 112. The beam size adjustment device 1426 may be motorized and include a beam expander 1427.

The RTP controller 1410 and the Galvano mirror circuit 1413 may operate as a X-Y galvanometer scanning system. The first mirror 1414 may be used to move the laser beam across a surface of the substrate 112 in a first (or X) direction. The second mirror 1416 may be used to move the laser beam across the surface of the substrate in a second (or Y) direction. The controller 1408 and/or the RTP controller 1410 may move the mirrors 1414, 1416 via motors 1430, 1432.

The optical beam folding assembly 1418 may include a set of mirrors for reflecting a received laser beam. The optical beam folding assembly 1418 may include any number of mirrors. As an example, 4 mirrors 1452, 1454, 1456, 1458 are shown. The mirrors may have different sizes, be positioned at different angles, and be positioned in different locations within a housing 1459. The housing 1459 may have a first (or input) window 1460 and a second (or output) window 1461 through which a laser beam is passed. In the example shown, three laser beams 1462, 1464, 1466 are shown; each of which having respective light rays. The three laser beams are provided at respective times and by moving the mirrors 1414, 1416 to respective positions. Any number of laser beams may be generated. In one embodiment, the Galvano mirror circuit is included in the housing 1459. The Galvano mirror circuit 1413 in combination with the optical beam folding assembly 1418 or the optical beam folding assembly 1418 alone may be referred to as a collimating assembly.

The optical beam folding assembly 1418 increases the distance that the laser beam travels from the second mirror 1416 to the substrate 112 while minimizing distance between the second mirror 1416 and the substrate 112. The increased travel distance collimates the laser beam prior to being received at the substrate. This provides a compact design. The optical beam folding assembly 1418 is also less expensive to manufacture than a tele-centric lens assembly.

The set of mirrors of the optical beam folding assembly 1418 are positioned and oriented to direct the laser beam received from the second mirror 1416 to be orthogonal (or within a predetermined angle of 90° relative) to the surface of the substrate 112. As the laser beam is moved across the surface of the substrate 112, the optical beam folding assembly 1418 maintains the laser beam in this orthogonal or semi-orthogonal relationship with the surface of the substrate 112.

As an example, a laser beam out of the beam shaping optics 1412, the acousto-optic modulator 1423 and/or the beam size adjustment device 1426 may be focused at the a center of the second mirror 1416 and then be directed through optical beam folding assembly 1418, where the laser beam is collimated and provided to the substrate 112. Focusing the laser at an input pupil of the second mirror (or lens) 1416 aids in providing a collimated beam at an upward facing surface of the substrate 112.

As an example, the laser beam generated by the laser 1404 may be 355 nm in diameter. The laser 1404 may operate in the pulse mode or the CW mode. The beam shaping optics 1412, the beam size adjustment device 1427, and the optical beam folding assembly 1418 may generate a 2 centimeter by 2 centimeter square beam that is received at the substrate 112. The RTP controller 1410 may move the mirrors 1414, 1416 to perform a 200 Hz scan across a surface of the substrate 112. The RTP controller 1410 may scan over all dies and/or an upward facing surface area (e.g., for a 300 mm diameter substrate, the 2.83×10⁵ mm upward facing surface area of the substrate) within a 1 second period of time. This may include scanning over, for example, 160 dies of the substrate within 1 second. The scanning includes moving the laser beam from die-to-die and heating each die for a predetermined period of time (e.g., an overall period of one or more pulses of the laser beam).

The substrate processing system 1400 may include the temperature control system 150, which may be used to control a temperature of the substrate support 110 and the substrate 112. The temperature control system 150 may include the one or more temperature sensors 156 to sense temperatures of one or more locations or zones of the substrate support 110.

The processes of ALD and ALE depend on iteratively performing a first operation A followed by a second operation B with a pump/purge operation being performed between operations A and B. This is true independent of the type of heat source utilized. For example, a full wafer surface may be dosed with a first gas to form a saturated monolayer. Any residual amount of the first gas may then be pumped out of a corresponding process chamber. The full wafer surface may then be exposed to second gas and/or an energy source (e.g. energetic ions or ultra-violet photons) followed by a pumping out of product (or remaining) gases. These operations may then be repeated until a predetermined deposited film thickness is obtained or a predetermined etched depth is reached.

For laser-based substrate processing, a laser beam is focused to an area much smaller than that of an upward facing surface area of a substrate (e.g., a 300 mm in diameter substrate having a upward facing surface area of approximately 2800 cm²) in order to heat the surface to a predetermined temperature. In addition, an amount of time to perform pulsed laser annealing (a predetermined number of picoseconds or nanoseconds) is several orders of magnitude smaller than the few seconds typically needed to (i) dose one or more upper and/or outer surfaces of a wafer the full wafer, or (ii) pump out gases in the processing chamber.

Thus, by using the implementations disclosed above, a laser beam may be focused to a size of a chip (or die) of a substrate and the laser beam is then stepped over a surface of the substrate and pulse synchronized with an amount of time involved to reposition the laser beam. Thus, the laser beam is ON when over a chip and is OFF while being transitioned to a next chip.

For example, if a chip has an upward facing surface area of 1 cm×1 cm, then the size of the generated laser beam is also 1 cm×1 cm. As an example, the surface area of a substrate may be dosed followed by pumping out gases and then the laser beam may be stepped from one chip to the next using one of the substrate processing systems disclosed herein. The laser beam may be pulsed ON over each of the chips in succession. Subsequent to pulsing the laser ON over each of the chips of the substrate, the substrate may then be dosed again and this process may be repeated until a predetermined etch depth or a predetermined deposited thickness has been reached for each die. The laser beam may be stepped over all of the chips of a substrate in less than 1-3 seconds, which is similar to an amount of time associated with gas dosing and gas purging operations. Thus, laser annealing time is reduced and substrate throughput is high and inexpensive. This also decreases ON time of the laser and the ratio of time to perform an annealing process on the chips of a substrate relative to the amount of time associated with corresponding dosing and purging.

In one embodiment, a duty cycle of a laser is synchronized with time to steer the associated laser beam from die to die. For example, if there are 160 2 cm-by-2 cm dies on a substrate, then a center of the laser beam is repositioned a distance of a little more than approximately 2 cm (or width of a die plus a gap between adjacent dies) between each laser pulse. If the whole substrate is scanned in a 1 second period of time, then the time associated with each laser pulse cycle is 1/160 seconds.

As an example, an entire substrate may be dosed, gases are pumped out of a corresponding processing chamber, and the laser is stepped from one die to the next pulsing ON over each die in succession. The substrate may then be dosed again and the process is repeated. This provides a quick annealing process. If laser annealing of a full substrate surface took a long time (e.g. 10 minutes), then substrate throughput would be low and expensive. By providing a laser annealing process where a full substrate surface is scanned in a short period of time (e.g., 1 second), the time gating items are substrate dosing and gas purging rather than laser annealing.

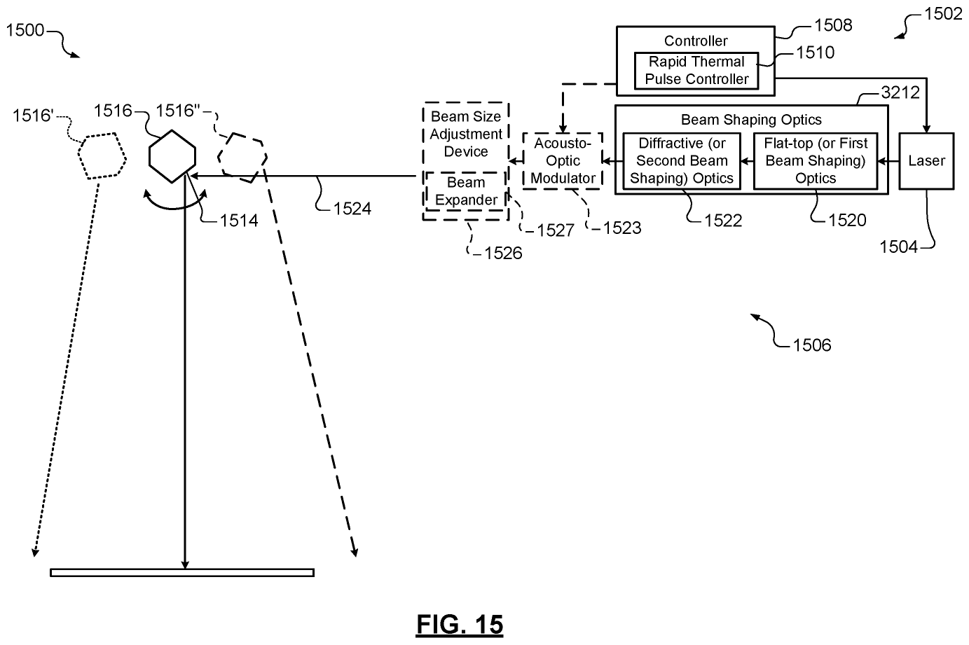

FIG. 15 shows a substrate processing system 1500 incorporating a RTP system 1502 including a laser 1504, a lens circuit 1506 and a controller 1508 with a RTP controller 1510. The substrate processing system 1500 may operate similar to the substrate processing system 200 of FIG. 2, the substrate processing system 1200 of FIG. 12 and/or the substrate processing system 1400 of FIG. 14. The laser 1504 is a heat source that may be pulsed (or modulated) by the RTP controller 1510 during RTP operations based on a control signal received from the RTP controller 1510. This may occur during ALE and ALD processes.

The lens circuit 1506 includes beam shaping optics 1512 and at least one of a mirror 1514 and a polygon scanner 1516. In one embodiment, the mirror 1514 is included and the polygon scanner 1516 is not included. In another embodiment, the mirror 1514 is implemented as one side of the polygon scanner 1516. The polygon scanner 1516 may have one or more mirrors. In one embodiment each side surface of the polygon scanner 1516 has a mirror. In the example shown, the polygon scanner has 6 side surfaces and two end surfaces. The polygon scanner may have any number of sides. In one embodiment, the mirror 1514 is rotated via a motor, such as one of the motors of FIGS. 2, 12, 14. In another embodiment, the polygon scanner 1516 is rotated via the motor.

The motor may be unidirectional or bi-directional, such that a shaft of the motor may be driven in forward and reverse directions. The motor may rotate the mirror and/or polygon scanner, such that a laser beam is no longer being reflected off a first portion of a first mirror, but rather is reflected off a second portion of the first mirror. The shaft of the motor may then be returned to the initial position, such that the laser beam is reflected off the first portion of the first mirror, or may be rotated such that the laser beam is reflected off a different mirror. In one embodiment, the motor is uni-directional and thus the shaft of the motor is rotated in a same direction. Instead of rotating the shaft in a reverse direction and returning to an initial position when rescanning a substrate, the polygon scanner may be rotated such that the laser beam is reflected off of the next adjacent mirror on the polygon scanner. This can have a same effect as returning to the initial position.

The beam shaping optics 1512 may include flat-top (or first beam shaping) optics 1520 and second beam shaping optics 1522. The flat-top optics 1520 are used to convert a laser beam received from the laser 1504, where the laser beam has a Gaussian distribution, into a flat-top beam. A temperature profile of the laser beam is also Gaussian. The second beam shaping optics 1522 convert the flat-top circular beam out of the flat-top optics 1520 to a line beam 1524 having an oval-shaped cross section, as shown in FIG. 16. The line beam 1524 may have a Gaussian intensity and/or temperature distribution in a first (or x) direction and a substantially “flat-top” or uniform intensity and/or temperature distribution in a second (or y) direction. The length L1 of the cross-section of the line beam 1524 in the y direction may be greater than a diameter of the substrate 112. As an example, the length L1 may be 320 mm and the diameter of the substrate may be 300 mm. In one embodiment, the line beam 1524 has (i) a substantially “flat-top” or uniform intensity in a center portion 1500 of the line beam 1524 and provides a uniform temperature distribution over a surface of the substrate 112, and (ii) end portions 1502 with sharply decreasing in intensity distributions from the center portion 1500 to a radially outermost edge 1504 of the substrate 112. In FIG. 16, the center portion 1500 of the cross-section of the line beam 1524 has a length L2, which is equal to or nearly the same as the diameter of the substrate 112. The substrate 112 may be disposed on a substrate support (e.g., the substrate support 110 of FIG. 1).

In the example shown in FIG. 15, the polygon scanner 1516 is shown in three rotated positions, two of which are illustrated by dashed representations 1516′ and 1516″. Although the representations 1516′ and 1516″ are shown to the left and right of the polygon scanner 1516, in actuality the polygon scanner is stationary and is simply rotated to scan over the substrate 112. This provides one-dimensional movement of the line beam across the substrate 112 for a quick scan (i.e. short scan times). No tele-centric lens assembly and/or optical beam folding assembly is utilized for the embodiment of FIG. 15.

The laser 1504 may be operated in a pulse mode or a continuous wave (CW) mode. During the pulse mode, the output of the beam shaping optics 1512 may be provided directly to a beam size adjustment device 1526. During the pulse mode, the RTP controller 1510 may control a pulse rate of the laser beam, such that pulse duration is in a pico-second or a nanosecond range. An acousto-optic modulator 1523 may be included when the laser 1504 is being operated in the CW mode. The acousto-optic modulator 1523 may be controlled by the RTP controller 1510. In one embodiment, the RTP controller 1510 generates a RF control signal, which is provided to the acousto-optic modulator 1523. The RF control signal is provided to control a change in a refractive index of a crystal of the acousto-optic modulator 1523. The refractive index of the crystal changes based on a frequency of the RF control signal. The laser beam provided from the beam shaping optics 1512 to the acousto-optic modulator 1523 is deflected by the crystal based on a frequency of the RF signal. The crystal performs as a laser shutter that permits or prevents passage of the laser beam to the beam size adjustment device 1526, the mirror 1514 and/or the polygon scanner 1516. In one embodiment, the RTP controller 1510 controls the frequency of the RF control signal, such that the continuous wave laser beam out of the beam shaping optics 1512 is effectively pulsed (or modulated) by the acousto-optic modulator 1523. The laser beam is pulsed, such that a period of each pulse is in a micro-second or a millisecond range. As a result, use of the acousto-optic modulator 1523 allows for pulsed laser beam generation having longer duration pulses for increased heating per pulse.

The beam size adjustment device 1526 may be disposed between the beam shaping optics 1512 and the mirror 1514 and/or the polygon scanner 1516. The beam size adjustment device 1526 may adjust a size of the line beam to be greater than a diameter of the substrate 112. The beam size adjustment device 1526 may be motorized and include a beam expander 1527.

The RTP controller 1510, the mirror 1514 and/or the polygon scanner 1516 may operate as a uni-dimensional scanning system. The mirror 1514 and/or the polygon scanner 1516 may be rotated to move the laser/line beam 1524 across the surface of the substrate 112 in, for example, a first (or X) direction. The controller 1508 and/or the RTP controller 1510 may rotate the mirror 1514 and/or the polygon scanner 1516 via a corresponding motor, as described above to scan across the surface of the substrate 112. In each position of the line beam on the surface of the substrate, the line beam heats portions of the dies of the substrate 112 in a y-direction. One or more pulses may be generated at each position of the line beam. The line beam may be cycled across the surface multiple times to remove a predetermined thickness (or thicknesses) of material from the substrate 112.

FIG. 16 shows cross-sectional views of a circular beam 1610 and the line beam 1624. The beam shaping optics 1512 convert the circular beam 1610, which may be outputted from the laser 1504 of FIG. 15, to the line beam 1524. The line beam has an oval-shaped cross section and may have a Gaussian distribution in the x-direction and a substantially uniform distribution in the y-direction. As an example, an incident angle between when the line beam is directed at a center of the substrate 112 and when the line beam is directed at a point near a radially outermost edge of the substrate 112 may be 8.53°. Normal energy density of the line beam at the center position may be 1 and at the radially outermost edge position may be 0.989. Beam size deviation between the two positions may be 1.12 μm.

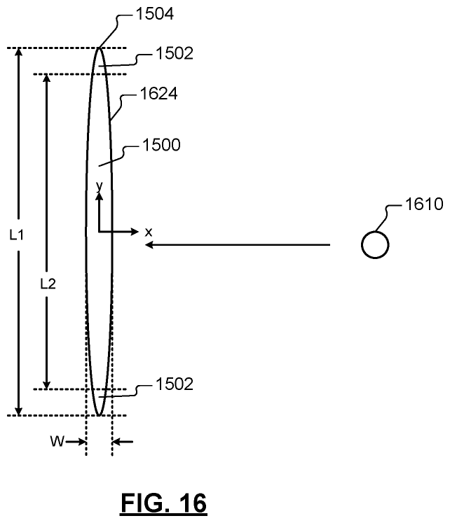

FIG. 17 shows a metal ALE method implementing non-rapid thermal pulsing and/or non-pulsed (constant) thermal annealing as described herein. The metal ALE method may include the metal ALE process of FIG. 4, which may be iteratively performed, where each iteration is referred to as a cycle. Although the following operations are primarily described with respect to the implementations of FIGS. 1-2 and 4, the operations may be easily modified to apply to other implementations of the present disclosure. The operations may be iteratively performed. Certain operations, shown with dashed lines in FIG. 17, may not be performed or may be skipped for a current cycle.

The method may begin at 1700. At 1702, a substrate (e.g., the substrate 112 of FIGS. 1 and 2 and/or a 300 mm diameter substrate) is arranged in a processing chamber. At 1704, chamber operating parameters such as substrate support temperatures, chamber pressures, RF power and bias power levels, and gas flow rates are set. During operation 1704, types of gases, vapors, liquids, ligands, organic vapors, etc. to be introduced during the following operations 1708, 1710. During operation 1704, volumes, flow rates, and/or pressures of the gases, vapors, liquids, ligands, organic vapors, etc. introduced during the operations 1708, 1710 may also be determined. Energy levels for operation 1714 may also be selected. The stated operating parameters may be selected and/or adjusted to adjust etch rates per cycle of the metal ALE process being performed. The etch rates are tunable. In one embodiment, the gases, vapors, liquids, plasmas, and/or chemicals used to perform surface modification operations are selected and corresponding volumes, amounts, pressures, flow rates and start, end and/or duration times of the flow of the gases, vapors, liquids, plasmas and/or chemicals are determined. This may include durations: during which flow is stopped; durations that a substrate is exposed to one or more gases, vapors, liquids, plasmas and/or chemicals; purge times; and/or other related timing. Temperature levels and RTP energy levels and corresponding timing may also be determined. The stated information may be determined for each cycle being performed.

At 1706, a surface of the substrate is cleaned. As an example the substrate may include an upper (or top) layer that is disposed on a base layer. The upper layer may include or consist of a metal, a metal oxide or a metal nitride. The upper surface of the upper layer may be cleaned.

At 1708, pretreatment is performed including exposing one or more surfaces and/or layers of the substrate that include a metal, a metal oxide or a metal nitride with, for example, molecular oxygen (O₂) plasma, ozone (O₃), hydrogen peroxide (H₂O₂), water vapor plasma, hydrogen (H₂) plasma, molecular chlorine (Cl₂) plasma, hydrazine (N₂H₄), ammonia (NH₃) plasma, and/or other gas. The surface modification may include a non-plasma process, such as flow of chemicals, hydrogen peroxide (H₂O₂) vapor, water (H₂O) vapor, hydrazine (N₂H₄), and/or other chemical reactant. In another embodiment, the surface modification includes a plasma process, such as flow of molecular oxygen (O₂) plasma, molecular hydrogen (H₂) plasma, an ammonia (NH₃) plasma, a water (H₂O) plasma, and/or other plasma. Operation 1708 may be performed to convert a metal to a metal oxide or a metal halide. As an example, this may include supplying O₂ plasma to convert TiN (Ti³⁺) to TiO₂ (Ti⁴⁺), which may occur at room temperature or at other temperatures. This operation may be performed for de-chlorination and surface activation. As an example, a plasma gas mixture including hydrogen (H₂) gas or ammonia (NH₃) gas species is supplied to the processing chamber. In one embodiment, surface modification is performed without plasma, but by using gases having a preselected chemistry.

At 1709, the substrate is optionally preheated. This may include increasing temperature of the substrate support (or a plate thereof) and/or temperature within the corresponding processing chamber as described above. As an example, the temperature of the substrate, substrate support, and/or interior of the processing chamber may be increased to a predetermined temperature (e.g., 200° C.). In an embodiment, operation 1709 is not performed and the substrate is maintained at a room temperature. In one embodiment, the temperature of the substrate, substrate support and/or interior of the processing chamber are at temperatures greater than or equal to a room temperature and less than a boiling point of a complex metal to be formed as a result of performing the following operation 1710.

At 1710, atomistic adsorption is performed including introduction of one or more reactive free ligands, such as hexafluroacetylacetone Hhfac and/or acetylacetone Hacac, and/or introduction of one or more other organic gases, vapors and/or reactants to be adsorbed into the substrate. The metal-free ligand may include molecular chlorine (Cl₂), ethanol (EtOH), and/or other organic vapor. In an embodiment, the metal-free ligand is Cl₂. This operation includes converting one or more upper and/or outer surfaces/layers of the substrate that was modified at 1708 into a layer having a metal complex. Operation 1710 may occur at temperatures, for example, greater than or equal to a room (or ambient) temperature and less than a boiling point of the metal complex. The one or more ligands introduced may be selected based on the metal, metal oxide, and/or metal nitride being etched, the pre-treatment performed, the temperature of the surface/layer being etched, the energy level used for etching, etc. This enables precise and highly selective etching including selective etch depths and etch rates for surfaces having different metals and/or metal compounds.

At 1712, the corresponding process chamber is purged of gases. At 1714, extended (or long) pulsed or non-pulsed thermal annealing is performed. This may include, for example, heating the substrate support and/or using flash lamps, a laser or other suitable lamps (e.g., infrared lamps) capable of providing extended length heating pulses. The substrate support may be heated, for example, to temperatures between 250° C. to 400° C. Cl₂ may not react with a surface of the substrate at temperatures greater than 400° C. The extended length heating pulses are longer than a predetermined length, for example, the pulses may each be longer than 20 ms when a flash lamp is used and longer than 20 ps when a laser is used. The heating may be provided for a predetermined period of time and then removed. In one embodiment, heating pulses are not provided and the substrate support and/or the processing chamber is heated.

At least operations 1708-1715 may be iteratively performed including modulating surface or upper portion temperatures of the substrate. Thermal annealing is performed at 1714 for desorption/removal purposes. Temperatures may be increased to evaporate certain molecules.

No inorganic salt or additional metal complex is produced when performing the above stated operations. An additional metal complex can be produced when, for example, a metal precursor is introduced. The above operations do not include introduction of a metal precursor. Incomplete organic residual may be cleaned easily by introducing hydrogen plasma or oxygen plasma in a surface refresh operation, such as at 1715.

At 1715, the surface of the substrate may be refreshed by purging the process chamber with a purge gas (e.g., argon (Ar) gas) to perform ion bombardment and remove the modified portion(s) of the substrate. In one embodiment, the processing chamber is purged between one or more consecutive pairs of provided rapid thermal pulses. In an embodiment, the gases are purged from the processing chamber between each consecutive pair of pulses. This enables performance of multiple plasma and/or gas phase processes within the processing chamber. In an embodiment, substrate support cooling is provided during and/or subsequent to pulsed rapid thermal annealing to aid in maintaining temperatures of the base and/or bulk of the substrate during pulsed rapid thermal annealing and to aid in rapid cooling of the substrate subsequent to performing pulsed rapid thermal annealing.

At 1716, the controller 180 or 208 determines whether N cycles have been completed, where N is an integer greater than or equal to 1. If N cycles have been completed, operation 1718 is performed, otherwise operation 1708 is performed. At 1718, the controller 180 or 210 may optionally perform a second (or post) annealing operation. At 1719, the controller 180 or 210 may determine, for a current die, whether to perform another process and/or whether to change and/or reiterate a current process. If another process is to be performed, operation 1704 may be performed, otherwise operation 1720 may be performed when a laser and a lens circuit is utilized as in the embodiment of FIG. 2. If flash lamps are used as in the embodiment of FIG. 1, the method may end at 1722 when another process or a change in a current process is not performed. If a process is to be performed on another die, operation 1724 is performed, otherwise the method may end at 1722.

At 1724, the controller 208 moves the mirrors 214, 216 to change an image plane position of a laser beam to be over a different die of the substrate 112. As an example, a 2 cm×2 cm laser beam may be moved from being over a first die to being over a second die. The described method may be iteratively performed to scan the laser beam over tens to hundreds of dies on the substrate. Movement of the mirrors 214, 216 may be synchronized with a pulsing repetition rate of the laser 204 to provide one or more shots per die.

The above-described operations are meant to be illustrative examples. The operations may be performed sequentially, synchronously, simultaneously, continuously, during overlapping time periods or in a different order depending upon the application. Also, any of the operations may not be performed or skipped depending on the implementation and/or sequence of events.

The above-described method provides highly selective ALE with high throughput with improved ALE thickness control over that provided during plasma etching. The examples include introducing CL₂, which attacks TiO₂ and does not react with TiN, which provides a self-limiting process. The introduction of O₂ plasma to convert Ti to an oxidized state is an effective and fast process and the introduction of Cl₂ to remove TiO₂ leaves no residual. Also, Cl₂ does not react with SiO₂.

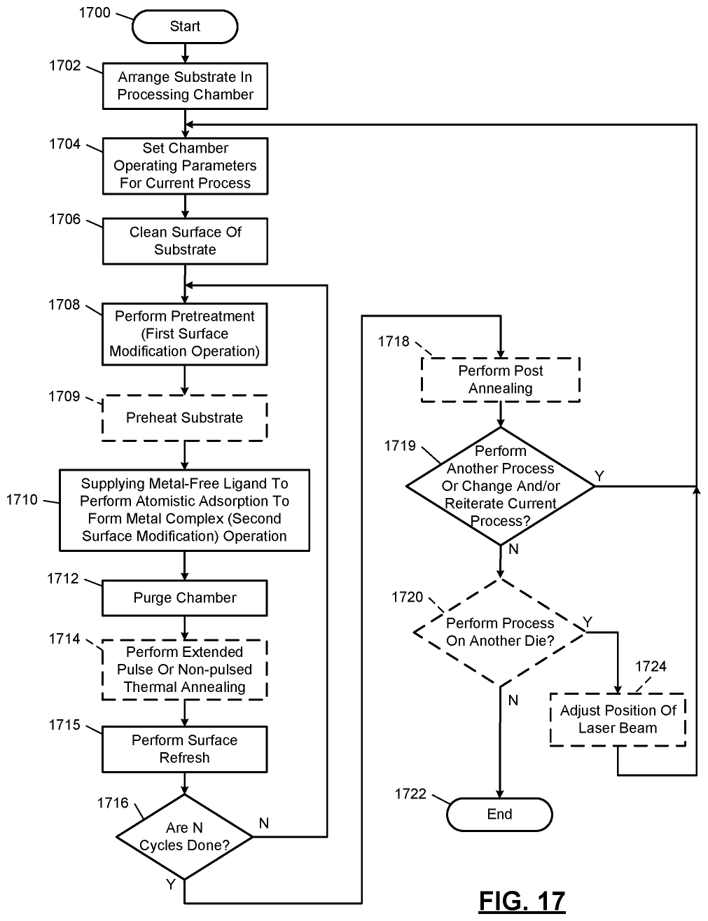

A fill portion of a via can contribute most of the resistance in a back-end-of-line (BEOL) process. To reduce this resistance, a bottom portion of the via may be removed using the following method of FIG. 18, which may be referred to as a directed anisotropic BEOL barrier removal method with rapid thermal pulsing. This direct ligand process that may be used for selective removal of portions of a metal nitride layer. The portions are removed without damage to an underlayer. There is also no thermal budget issue due to the inclusion of a conductive line (e.g., copper (Cu) line). As an example, a top layer of at a bottom of a via may be removed while leaving sidewalls of the via. A top layer outside of the via may also be removed. This is further described below with respect to the method of FIG. 18.

FIG. 18 shows a BEOL metal barrier ALE method implementing low chamber pressure and/or plasma pressure control, bias power control, and RTP thermal annealing. This method may be referred to as a metal nitride ALE method when portions of a metal nitride layer are being removed and may include the metal ALE process of FIG. 4. This method may be iteratively performed, where each iteration is referred to as a cycle. Although the following operations are primarily described with respect to the implementations of FIGS. 1-2, 4 and 19, the operations may be easily modified to apply to other implementations of the present disclosure. Certain operations, shown with dashed lines in FIG. 18, may not be performed or may be skipped for a current cycle.

The method may begin at 1800. At 1802, a substrate (e.g., the substrate 112 of FIGS. 1 and 2 and/or a 300 mm diameter substrate) is arranged in a processing chamber. At 1804, chamber operating parameters such as substrate support temperatures, chamber pressures, RF power and bias power levels, and gas flow rates are set. During operation 1804, types of gases, vapors, liquids, ligands, organic vapors, etc. to be introduced during the following operations 1808, 1810. During operation 1804, volumes, flow rates, and/or pressures of the gases, vapors, liquids, ligands, organic vapors, etc. introduced during the operations 1808, 1810 may also be determined. Energy levels for operation 1814 may also be selected. The stated operating parameters may be selected and/or adjusted to adjust etch rates per cycle of the metal ALE process being performed. The etch rates are tunable. In one embodiment, the gases, vapors, liquids, plasmas, and/or chemicals used to perform surface modification operations are selected and corresponding volumes, amounts, pressures, flow rates and start, end and/or duration times of the flow of the gases, vapors, liquids, plasmas and/or chemicals are determined. This may include durations: during which flow is stopped; durations that a substrate is exposed to one or more gases, vapors, liquids, plasmas and/or chemicals; purge times; and/or other related timing. Temperature levels and RTP energy levels and corresponding timing may also be determined. The stated information may be determined for each cycle being performed.

At 1806, a surface of the substrate is cleaned. As an example the substrate may include an upper (or top) layer that is disposed on a base layer. The upper layer may include or consist of a metal, a metal oxide or a metal nitride. The upper surface of the upper layer may be cleaned.

At 1808, pretreatment is performed including exposing one or more surfaces and/or layers of the substrate that include a metal, a metal oxide or a metal nitride with, for example, molecular oxygen (O₂) plasma, ozone (O₃), hydrogen peroxide (H₂O₂), water vapor plasma, hydrogen (H₂) plasma, molecular chlorine (Cl₂) plasma, hydrazine (N₂H₄), ammonia (NH₃) plasma, and/or other gas. In one embodiment, O₂ pmasa is introduced. In another embodiment H₂ plasma is introduced. The surface modification may include a non-plasma process, such as flow of chemicals, hydrogen peroxide (H₂O₂) vapor, water (H₂O) vapor, hydrazine (N₂H₄), and/or other chemical reactant. In another embodiment, the surface modification includes a plasma process, such as flow of molecular oxygen (O₂) plasma, molecular hydrogen (H₂) plasma, an ammonia (NH₃) plasma, a water (H₂O) plasma, and/or other plasma.

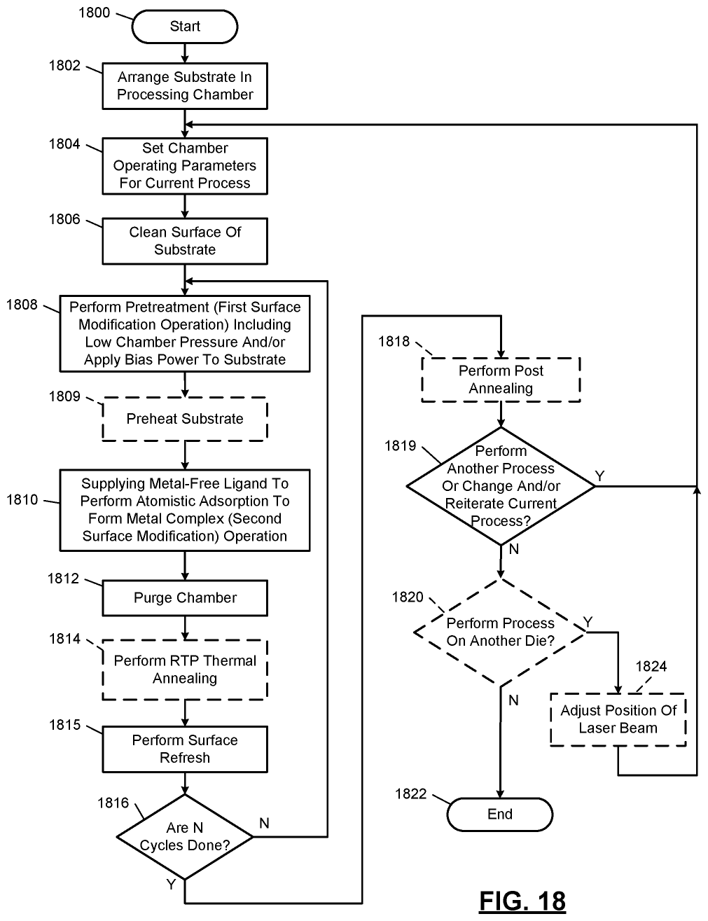

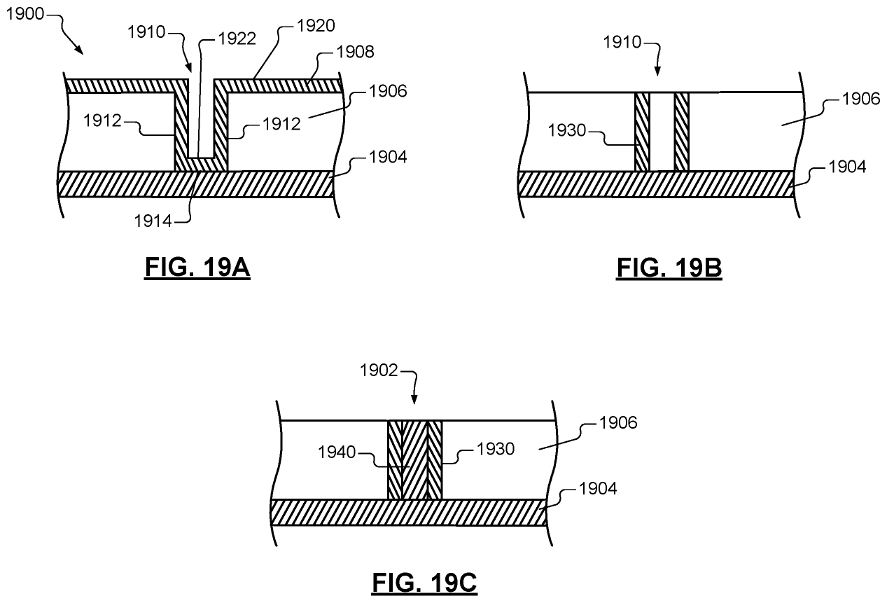

During this operation, plasma chamber pressure and/or pressure of plasma included therein is maintained at a low pressure (e.g., a pressure less than a predetermined pressure). A bias power (bias current and/or voltage) is supplied via, for example, the RF generator 120-2 of FIG. 1 to bias the substrate via the substrate support. As an example, the bias current and/or voltage may be greater than a predetermined bias current and/or voltage. As an example, one or more portions of the substrate may be biased. Operation 1808 may be performed to modify selective portions of a metal nitride layer. The low pressures and the selective biasing of the substrate allow selective modification to the top or metal nitride layer. Referring now also to FIG. 19A, which shows a portion 1900 of a substrate in which a via 1902 is being formed. The substrate includes a conductive uderlayer 1904, an intermediate layer 1906, and a top layer 1908. The intermediate layer 1906 may be a dielectric layer and be formed of a dielectric material. The intermediate layer 1906 includes a hole 1910. The top layer 1908, which may be formed of a metal nitride, such as TaN or TiN, is in contact with and disposed across a top surface of the intermediate layer 1906 and fills a portion of the hole 1910. The top layer 1908 is on the sidewalls 1912 and bottom 1914 of the hole 1910 (or top portion of the conductive layer 1904 in the hole 1910). The intermediate layer 1906 is in contact with and disposed on the conductive underlayer 1904. The conductive underlayer 1904 may be formed of copper (Cu), cobalt (Co) and/or one or more other suitable conductive materials.

During operation 1808, a portion 1920 of the top layer 1908 that are in contact with the top surface of the intermediate layer 1906 and a portion 1922 of the top surface of the conductive underlayer 1904 that is in the hole 1910 is modified for removal during operation 1814. Sidewall portion 1930 of the top layer 1908 remains in the hole 1910. A result of operations 1808 and 1814 is shown in FIG. 19B. Subsequent to the method of FIG. 18, the hole 1910 having sidewall 1930 may be filled with a conductive material 1940 to form the via 1902, as shown in FIG. 19C. The conductive material may be Cu, Co and/or other suitable conductive material.

During operation 1808 and in an embodiment, an 02 plasma may be provided, with bias power supplied to the substrate and a low process chamber pressure. Oxidizing ions from the plasma may be extracted and the substrate may be biased to a sufficiently high voltage to provide directional bombardment of the oxidizing ions. In another embodiment, hydrogen peroxide (H₂O₂) and/or ozone (O₃) is provided at low pressure. O₂ may provide an increased etch rate as compared to O₃. In another embodiment, the provided plasma, the process chamber, and/or the supplied one or more gases are at a low pressure. In one embodiment, bias power is not provided. In an embodiment, the bottom portion 1922 is oxidized or hydrogenated and the sidewall portion 1930 is not oxidized or hydrogenated. The oxidized or hydrogenated areas are reactive towards Cl₂ and/or metal free ligands and are able to be converted to a volatile species to be removed by rapid thermal pulsing.

At 1809, the substrate is optionally preheated. This may include increasing temperature of the substrate support and/or temperature within the corresponding processing chamber as described above. As an example, the temperature of the substrate, substrate support, and/or interior of the processing chamber may be increased to a predetermined temperature (e.g., 200° C.). In an embodiment, operation 1809 is not performed and the substrate is maintained at a room temperature. In one embodiment, the temperature of the substrate, substrate support and/or interior of the processing chamber are at temperatures greater than or equal to a room temperature and less than a boiling point of a complex metal to be formed as a result of performing the following operation 1810.

At 1810, atomistic adsorption is performed including introduction of one or more reactive free ligands, such as hexafluroacetylacetone Hhfac and/or acetylacetone Hacac, and/or introduction of one or more other organic gases, vapors and/or reactants to be adsorbed into the substrate. The metal-free ligand may include molecular chlorine (Cl₂), ethanol (EtOH), and/or other organic vapor. In an embodiment, the metal-free ligand is Cl₂. This operation includes converting one or more upper and/or outer surfaces/layers of the substrate that was modified at 1808 into a layer having a metal complex. Operation 1810 may occur at temperatures, for example, greater than or equal to a room (or ambient) temperature and less than a boiling point of the metal complex. The one or more ligands introduced may be selected based on the metal, metal oxide, and/or metal nitride being etched, the pre-treatment performed, the temperature of the surface/layer being etched, the energy level used for etching, etc. This enables precise and highly selective etching away of the portions 1920, 1922.

At 1812, the corresponding process chamber is purged of gases. At 1814, pulsed rapid thermal annealing is performed using, for example, flash lamps, a laser or other suitable lamps (e.g., infrared lamps) capable of being rapidly pulsed as described herein. In an embodiment, flash lamps are utilized providing a predetermined amount of thermal energy (e.g., 7 Joules (J) or 11 J). In another embodiment, pulsed laser is utilized.

At least operations 1808-1815 may be iteratively performed including modulating surface or upper portion temperatures of the substrate. The temperature of the surface or upper portion may be modulated multiple times in a single second. Pulsed rapid thermal annealing is performed at 1814 for desorption/removal purposes. This may include generating one or more thermal energy pulses to heat the modified portion of the substrate. Temperatures may be increased to evaporate certain molecules. Rapid thermal pulsing enables a clean reaction at surface of substrate, which frees the metal complex from the substrate.

No inorganic salt or additional metal complex is produced when performing the above stated operations. An additional metal complex can be produced when, for example, a metal precursor is introduced. The above operations do not include introduction of a metal precursor. Incomplete organic residual may be cleaned easily by introducing hydrogen plasma or oxygen plasma in a surface refresh operation, such as at 1815.

A base and/or bulk of the substrate is maintained at or below a predetermined temperature (e.g., less than or equal to 20° C.) during operation 1814. RTP enables one processing chamber configuration to be used with high throughput. Multiple processing operations may be performed in the single processing chamber. As another example, each of the pulses may be 0.1 millisecond (ms) in length and a temperature of a surface and/or a portion of the substrate may be increased up to 1000° C.

In some examples, each of the flash lamp pulses provides 5 J/cm² (i.e., energy per unit area of the substrate) to 80 J/cm². In some examples, each of the laser pulses provides 5 mJ/cm² to 80 mJ/cm². In some examples, the annealing is performed during a predetermined period in a range from 0.1 ms to 20 ms. In one embodiment, the flash lamp is used with pulse durations of 1 ms or the laser is used with pulse durations of 1 picosecond (ps) to heat the surface or upper portion of the substrate from an initial temperature to greater than 500° C. and then cooled back down to the initial temperature in less than 1 second (s).

Operations 1808, 1810, 1814 allow for controllable atom by atom removal of selective portions of a surface and/or upper layer of the substrate that was modified during operations 1808 and 1810. The rapid heating performed at 1814 provides an isotropic reaction without use of plasma. In addition, the claimed heating allows for rapid cool down, which also prevents thermal budget issues.

At 1815, the surface of the substrate may be refreshed by purging the process chamber with a purge gas (e.g., argon (Ar) gas) to perform ion bombardment and remove the modified portion(s) of the substrate. In one embodiment, the processing chamber is purged between one or more consecutive pairs of provided rapid thermal pulses. In an embodiment, the gases are purged from the processing chamber between each consecutive pair of pulses. This enables performance of multiple plasma and/or gas phase processes within the processing chamber. In an embodiment, substrate support cooling is provided during and/or subsequent to pulsed rapid thermal annealing to aid in maintaining temperatures of the base and/or bulk of the substrate during pulsed rapid thermal annealing and to aid in rapid cooling of the substrate subsequent to performing pulsed rapid thermal annealing.

At 1816, the controller 180 or 208 and/or rapid thermal pulse controller 182 or 210 determines whether N cycles have been completed, where N is an integer greater than or equal to 1. If N cycles have been completed, operation 1818 is performed, otherwise operation 1808 is performed. At 1818, the controller 180 or 210 may optionally perform a second (or post) annealing operation. At 1819, the controller 180 or 210 may determine, for a current die, whether to perform another process and/or whether to change and/or reiterate a current process. If another process is to be performed, operation 1804 may be performed, otherwise operation 1820 may be performed when a laser and a lens circuit is utilized as in the embodiment of FIG. 2. If flash lamps are used as in the embodiment of FIG. 1, the method may end at 1822 when another process or a change in a current process is not performed. If a process is to be performed on another die, operation 1824 is performed, otherwise the method may end at 1822.

At 1824, the controller 208 moves the mirrors 214, 216 to change an image plane position of a laser beam to be over a different die of the substrate 112. As an example, a 2 cm×2 cm laser beam may be moved from being over a first die to being over a second die. The described method may be iteratively performed to scan the laser beam over tens to hundreds of dies on the substrate. Movement of the mirrors 214, 216 may be synchronized with a pulsing repetition rate of the laser 204 to provide one or more shots per die.

The above-described operations are meant to be illustrative examples. The operations may be performed sequentially, synchronously, simultaneously, continuously, during overlapping time periods or in a different order depending upon the application. Also, any of the operations may not be performed or skipped depending on the implementation and/or sequence of events.

The above-described method of FIG. 18 is performed instead of performing a sputter clean process prior to Cu or Co deposition to fill a via. A portion of a TaN layer at a bottom of a via is removed to minimize and/or eliminate a resistance-capacitance (RC) issue. The method allows for the select removal of flat/horizontal monolayer portions of a top layer and corresponding surfaces.

The method of FIG. 18 may be used for isotropical and selective removal of, for example, metal nitride from 3-dimensional features, such as vias, holes, NAND memory features, etc. The method may be used for removal of a metal nitride layer from within a high aspect ratio hole. A front-end-of-line (FEOL) metal gate (MG) formed of TiN and having a predetermined depth may be removed isotropically using the stated method.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A atomic layer etch (ALE) system for performing a metal ALE process to etch a surface of a substrate, the ALE system comprising:
a processing chamber;
a substrate support disposed in the processing chamber and configured to support the substrate;
a first heat source;
a delivery system configured to supply at least one of a ligand or an organic species to the processing chamber; and
a controller configured to control the delivery system and the first heat source to perform an isotropic metal ALE process including
during an iteration of the isotropic metal ALE process, performing atomistic adsorption and pulsed thermal annealing,
during the atomistic adsorption, exposing the surface of the substrate to the at least one of the ligand or the organic species, wherein the at least one of the ligand or the organic species is void of a metal precursor and is selectively adsorbed to form a metal complex in the surface of the substrate, and
during the pulsed thermal annealing, pulsing the first heat source on and off a plurality of times to remove the metal complex from the substrate.

2. The ALE system of claim 1, wherein the surface includes at least one of a metal, a metal oxide, or a metal nitride.

3. The ALE system of claim 1, wherein, during the isotropic metal ALE process, the surface of the substrate is not exposed to a metal precursor.

4. The ALE system of claim 1, wherein the isotropic metal ALE process includes preheating the substrate, via a second heat source, prior to performing the atomistic adsorption.

5. The ALE system of claim 4, wherein the isotropic metal ALE process includes preheating the substrate to a temperature greater than or equal to an ambient temperature and less than a boiling point temperature of the metal complex.

6. The ALE system of claim 1, wherein the isotropic metal ALE process includes modifying the surface prior to performing the atomistic adsorption.

7. The ALE system of claim 6, wherein the modifying of the surface includes supplying a gas to react with the surface of the substrate without striking plasma.

8. The ALE system of claim 6, wherein the modifying of the surface includes supplying a gas to react with the surface of the substrate and striking plasma.

9. The ALE system of claim 6, wherein:
the surface includes the metal; and
the modifying of the surface includes converting the metal to a metal oxide or a metal halide.

10. The ALE system of claim 1, wherein:
during the atomistic adsorption, the surface of the substrate is exposed to the ligand; and
the ligand is a reactive free ligand.

11. The ALE system of claim 10, wherein the ligand is selected from a group consisting of hexafluroacetylacetone (Hhfac) and acetylacetone (Hacac).

12. The ALE system of claim 10, wherein the ligand is selected from a group consisting of molecular chlorine (Cl₂), ethanol (EtOH), and an organic vapor.

13. The ALE system of claim 1, wherein:
the isotropic metal ALE process includes a first modification operation and a second modification operation;
the atomistic adsorption corresponds to the second modification operation;
the controller is configured to perform a predetermined number of iterations of the isotropic metal ALE process; and
each of the predetermined number of iterations includes at least one of (i) supplying a different chemical species during the first modification operation than is supplied during a previous iteration of the isotropic metal ALE process, or (ii) supplying a different chemical species during the second modification operation than is supplied during a previous iteration of the isotropic metal ALE process.

14. A metal atomic layer etch (ALE) method for etching a surface of a substrate, the metal ALE method comprising:
disposing the substrate on a substrate support in a processing chamber;
a delivery system configured to supply at least one of a ligand or an organic species to the processing chamber; and
performing an isotropic metal ALE process including
during an iteration of the isotropic metal ALE process, performing atomistic adsorption and pulsed thermal annealing,
during the atomistic adsorption, exposing the surface of the substrate to the at least one of the ligand or the organic species, wherein the at least one of the ligand or the organic species is void of a metal precursor and is selectively adsorbed into the surface of the substrate to form a metal complex, and
during the pulsed thermal annealing, pulsing a heat source on and off a plurality of times to remove the metal complex from the substrate.

15. The metal ALE method of claim 14, wherein the surface includes at least one of a metal, a metal oxide, or a metal nitride.

16. The metal ALE method of claim 14, wherein, during the isotropic metal ALE process, the surface of the substrate is not exposed to a metal precursor.

17. The metal ALE method of claim 14, wherein the isotropic metal ALE process includes preheating the substrate prior to performing the atomistic adsorption to a temperature greater than or equal to an ambient temperature and less than a boiling point temperature of the metal complex.

18. The metal ALE method of claim 14, wherein the isotropic metal ALE process includes modifying the surface prior to performing the atomistic adsorption.

19. The metal ALE method of claim 18, wherein the modifying of the surface includes supplying a gas to react with the surface of the substrate without striking plasma.

20. The metal ALE method of claim 18, wherein the modifying of the surface includes supplying a gas to react with the surface of the substrate and striking plasma.

21. The metal ALE method of claim 18, wherein:
the surface includes the metal; and
the modifying of the surface includes converting the metal to a metal oxide or a metal halide.

22. The metal ALE method of claim 14, wherein:
during the atomistic adsorption, the surface of the substrate is exposed to the ligand; and
the ligand is a reactive free ligand.

23. The metal ALE method of claim 22, wherein the ligand is selected from a group consisting of hexafluroacetylacetone (Hhfac) and acetylacetone (Hacac).

24. The metal ALE method of claim 22, wherein the ligand is a reactive free ligand selected from a group consisting of molecular chlorine (Cl₂), ethanol (EtOH), and an organic vapor.

25. The metal ALE method of claim 14, wherein:
the isotropic metal ALE process includes a first modification operation and a second modification operation;
the atomistic adsorption corresponds to the second modification operation;
a predetermined number of iterations of the isotropic metal ALE process are performed; and
each of the predetermined number of iterations includes at least one of (i) supplying a different chemical species during the first modification operation than is supplied during a previous iteration of the isotropic metal ALE process, or (ii) supplying a different chemical species during the second modification operation than is supplied during a previous iteration of the isotropic metal ALE process.

26. A atomic layer etch (ALE) system for performing a metal ALE process to etch a surface of a substrate, the ALE system comprising:
a processing chamber;
a substrate support disposed in the processing chamber and configured to support the substrate;
a heat source configured to heat at least one of the substrate support or the processing chamber;
a delivery system configured to supply at least one of a ligand or an organic species to the processing chamber; and
a controller configured to control the delivery system and the heat source to perform an isotropic metal ALE process including
during an iteration of the isotropic metal ALE process, modifying the surface, performing atomistic adsorption and thermal annealing,
during the modifying of the surface, supplying a gas to react with the surface of the substrate,
during the atomistic adsorption, exposing the surface of the substrate to the at least one of the ligand or the organic species, wherein the at least one of the ligand or the organic species is void of a metal precursor and is selectively adsorbed to form a metal complex in the surface of the substrate, and
during the thermal annealing, activating the heat source to remove the metal complex from the substrate.

27. The ALE system of claim 26, wherein the gas includes oxygen (O₂).

28. The ALE system of claim 26, wherein the ligand includes chlorine (Cl₂).

29. The ALE system of claim 26, wherein the thermal annealing includes:
not pulsing the heat source; or
pulsing the heat source with extended pulses having lengths greater than or equal to a predetermined length.

30. A atomic layer etch (ALE) system for performing a metal ALE process to etch a surface of a substrate, the ALE system comprising:
a processing chamber;
a substrate support disposed in the processing chamber and configured to support the substrate;
a heat source configured to heat at least one of the substrate support or the processing chamber;
a delivery system configured to supply at least one of a ligand or an organic species to the processing chamber; and
a controller configured to control the delivery system and the heat source to perform a selective metal ALE process including
during an iteration of the selective metal ALE process, modifying the surface, performing atomistic adsorption and pulsed thermal annealing,
during the modifying of the surface, supplying a gas to react with selective portions of the surface of the substrate, wherein the modifying of the surface includes at least one of
biasing the selective portions of the surface,
supplying the gas at a pressure below a predetermined pressure, or
maintaining a pressure within the processing chamber at less than the predetermined pressure,
during the atomistic adsorption, exposing the surface of the substrate to the at least one of the ligand or the organic species, wherein the at least one of the ligand or the organic species is void of a metal precursor and is selectively adsorbed to form a metal complex in the surface of the substrate, and
during the rapid thermal annealing, pulsing the heat source on and off a plurality of times to remove the metal complex from the substrate.

31. The ALE system of claim 30, wherein the gas includes oxygen (O₂) or hydrogen (H₂).

32. The ALE system of claim 30, wherein the ligand includes chlorine (Cl₂).

33. The ALE system of claim 30, wherein the portions of the surface include:
a bottom portion of a top layer in a hole of an intermediate layer of the substrate; and
a top portion of the top layer disposed on the intermediate layer.

34. The ALE system of claim 33, wherein the portions of the surface do not include a sidewall portion of the top layer disposed on a sidewall of the hole.
